(19) United States
(12) Patent Application Publication
(10) Pub. No.: US 2003/0020889 A1
(43) Pub. Date: Jan. 30, 2003

(54) Stage unit, measurement unit and measurement method, and exposure apparatus and exposure method

(75) Inventor: Akira Takahashi, Kawasaki-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Nikon Corporation, Tokyo (JP)

(21) Appl. No.: 10/179,155

(22) Filed: Jun. 26, 2002

Related U.S. Application Data
(63) Continuation-in-part of application No. 09/919,940, filed on Aug. 2, 2001.

(30) Foreign Application Priority Data
Aug. 2, 2000 (JP) 2000-234,746
Jun. 26, 2001 (JP) 2001-193,174

(51) Int. Cl. G03B 27/42; G03F 9/00; G03C 5/00; G03B 27/32; G01B 11/00

(52) U.S. Cl. 355/53; 430/22; 430/30; 356/401; 355/77

(57) ABSTRACT

A substrate holder is mounted on a stage moving within a two-dimensional plane, and the substrate holder holds the substrate and is capable of rotating through substantially 180° around a predetermined rotation axis by a drive unit. Accordingly, in measuring a TIS of an alignment detection system, laborious operation where the substrate is removed from the substrate holder and mounted again on the substrate holder after the substrate has been rotated will not be necessary. In this case, since the rotation of the substrate is performed while the substrate is held on the substrate holder, there is no possibility of occurrence of shift of the central position and the like of the substrate between before and after the rotation. Therefore, the TIS measurement of the alignment detection system can be performed in a short time and with high accuracy.

### CROSS-REFERENCE TO RELATED APPLICATIONS

This application continues in part from U.S. Ser. No. 09/919,940, filed Aug. 2, 2001. The disclosure of said application is incorporated herein by reference.

### BACKGROUND OF THE INVENTION

1. Field of the Invention

The present invention relates to a stage unit, a measurement unit and a measurement method, and an exposure apparatus and an exposure method. More particularly, the present invention relates to a stage unit preferable as a positioning unit of a substrate, a measurement unit and measurement method suitable for measuring position of a mark formed on the substrate using the stage unit, and an exposure apparatus and an exposure method using the measurement unit and the measurement method respectively.

2. Description of the Related Art

To date, in a lithographic process to manufacture a semiconductor device, a liquid crystal display device and the like, an exposure apparatus has been used in which a pattern formed on a mask or a reticle (hereinafter, generally referred to as a “reticle”) is transferred onto a substrate such as a wafer or a glass plate (hereinafter, generally referred to as a “wafer”), which is coated with a resist or the like, via a projection optical system. In recent years, with higher integration of the semiconductor device, a reduction projection exposure apparatus of a step-and-repeat method (a so-called stepper) and a projection exposure apparatus of a sequential movement type such as a scanning projection exposure apparatus of a step-and-scan method (a so-called scanning stepper) where improvement is made to the stepper have been mainly used.

Since the semiconductor device and the like are formed by overlaying plural layers of patterns, overlay of a pattern already formed on the wafer and a pattern formed on the reticle must be precisely performed in the exposure apparatus such as the stepper. Accordingly, a position of a shot area on the wafer where the pattern is formed needs to be accurately measured. As a measurement method, the position of an alignment mark formed on each shot area on the wafer is measured by using an alignment detection system. In this case, to accurately measure the position of the alignment mark, it is desirable that an optical system constituting the alignment detection system does not have an aberration and the like. It is because a positional measurement error of the alignment mark occurs if the optical system has the aberration and the like.

However, since producing an alignment detection system having no aberration (zero aberration) in the optical system is practically impossible, a detection shift of the alignment detection system is normally measured and an alignment result (a measurement value) is corrected using the measurement result.

Generally, among optical aberrations of the alignment detection system, what is of a problem in an alignment measurement (a mark positional measurement using the alignment detection system) is a coma. The coma is a phenomenon that an image forming position of an image forming luminous flux, which transmitted a lens, shifts horizontally in accordance with a positional relation between a transmission position of the luminous flux in the lens and the center of the lens. Therefore, even if the optical system has the coma, a positional detection shift of the mark is so small that it can be ignored in the case where a line width and a pitch of the mark to be detected are wide and an angle of diffraction light is small. However, the positional detection shift of the mark is so large that it cannot be ignored when the line width and the pitch of the mark are narrow and the angle of the diffraction light is large. Specifically, the coma in the optical system results in occurrence of the detection shift because the image is formed on different positions when the line widths are different even when a line pattern is on the same position.

The following method is known for calculating the detection shift (most of which is the detection shift caused by the foregoing coma of the optical system, but it also includes the detection shift, due to processes, of the mark to be detected and the like) caused by the alignment detection system, that is, a TIS (Tool Induced Shift). Mark measurement is performed in both states of the wafer orientations 0° and 180° by the alignment detection system to calculate the TIS based on the measurement results. As described, since the image forming position is different in accordance with the line width if the optical system has the coma, the TIS measurement evaluates the detection shift by measuring position of the mark, having a narrow line width, relative to the mark of a wide line width as a reference.

A conventional measurement method of the TIS will be briefly described as follows. Although the positional measurement in a two-dimensional plane is performed in an actual wafer alignment, description is made for a one-dimensional measurement to make the description simple.

A wafer exclusively for measurement purpose (hereinafter, referred to as a “tool wafer” for convenience) is prepared, where a fiducial mark having the wide line width and an alignment mark having the narrow line width are formed on the surface. Then, the tool wafer is mounted on a wafer holder. In this case, the tool wafer is mounted on the wafer holder such that the fiducial mark and the alignment mark are arranged along an axis parallel to a predetermined axis (for example, an X-axis) on a predetermined orthogonal coordinate system, X coordinates of the alignment mark and the fiducial mark are severally measured by the alignment detection system, and a distance X₀ between both the marks are calculated from the measurement results. Herein, the X coordinate of the fiducial mark and the X coordinate of the alignment mark on a wafer coordinate system shall be represented by RM and AM respectively. The wafer coordinate system is the orthogonal coordinate system parallel to the foregoing orthogonal coordinate system having a central point (α,β) of the tool wafer as an origin. Representing the distance between both the marks as X, X=AM−RM (which is a real value).

As describe above, due to the narrow line width of the alignment mark, its measurement result includes certain amount of the TIS of the alignment detection system that cannot be ignored. But, the TIS included in the result of measuring the fiducial mark having the wide line width can be considered to be zero. Accordingly, the foregoing measured value X₀ is expressed by the following expression (1) with the measured values of the alignment mark and the fiducial mark on the X coordinate, the measured values being represented by AM₍₀₎ and RM₍₀₎ respectively,

$$\begin{matrix}{X}_{0} = A {M}_{( 0 )} - R {M}_{( 0 )} \\ = ( A M + α + T I S ) - ( R M + α ) \\ = A M - R M + T I S .\end{matrix} \qquad ( 1 )$$

Next, the wafer is removed from the wafer holder. The wafer is mounted on the wafer holder again after it is rotated through 180° centering around the wafer center (the foregoing origin of the wafer coordinate system), the positions of the alignment mark and the fiducial mark are measured in the same manner as described above, and a distance X₍₁₈₀₎ between both the marks is calculated. In this case, the measured value X₍₁₈₀₎ is expressed by the following expression (2) with the measured values of the alignment mark and the fiducial mark on the X coordinate, the measurement values being represented by AM₍₁₈₀₎ and RM₍₁₈₀₎ respectively,

$$\begin{matrix}{X}_{180} = R {M}_{( 180 )} - A {M}_{( 180 )} \\ = α - R M - ( α - A M + T I S ) \\ = A M - R M - T I S .\end{matrix} \qquad ( 2 )$$

The TIS of the alignment detection system is calculated by the foregoing expressions (1) and (2), which is shown as follows,

TIS=(X₀−X₁₈₀)/2. (3)

The TIS calculated as above is used as a correction value for the measured values of alignment marks formed on wafers to be actually exposed (in actual processes).

However, in the foregoing method of measuring TIS or the real value (AM−RM) excluding TIS by use of the alignment detection system, only the TIS or the value excluding TIS of the alignment detection system for the alignment mark formed on a tool wafer is measured. Therefore, accurately calculating the TIS of the alignment detection system for the alignment marks formed on wafers on which exposure is to be performed (actual process wafers) and correcting for the TIS is difficult, and thus, the alignment result on each actual process wafer cannot be corrected precisely.

Moreover, as described above, due to the operation that the tool wafer is once removed from the wafer holder, rotated through 180°, and mounted on the wafer holder again, the measurement operation takes much time, and a shift of the central position and a rotation shift of the wafer also can occur between before and after the rotation through 180°. In such a case, the measurement accuracy of the TIS decreases as a result.

### SUMMARY OF THE INVENTION

The present invention was made under such circumstances. Its first object is to provide a stage unit that is suitable to be used in the TIS measurement of a mark detection system, for example.

A second object of the present invention is to provide a measurement unit and measurement method that contributes to improving the accuracy in measuring the detection error inherent in a mark detection system.

A third object of the present invention is to provide an exposure apparatus and an exposure method that can improve exposure accuracy.

According to a first aspect of the present invention, there is provided a stage unit that holds the substrate, comprising a stage that moves within the two-dimensional plane; a substrate holder, which is mounted on the stage, that holds the substrate and is capable of rotating through substantially 180° around a predetermined rotation axis orthogonal to the two-dimensional plane; and a drive unit that drives and rotates the substrate holder.

According to the stage unit, the substrate holder is mounted on the stage that moves within the two-dimensional plane, and the substrate holder holds the substrate and is capable of rotating through substantially 180° around the predetermined rotation axis orthogonal to the two-dimensional plane by the drive unit. Specifically, the substrate can be rotated through substantially 180° without removing it from the substrate holder. Thus, for example, in measuring the TIS of the alignment detection system, laborious operation that the substrate is removed from the substrate holder and mounted again on the substrate holder after the rotation will not be necessary. In this case, since the rotation of the substrate is performed while the substrate is held on the substrate holder, there is no possibility of occurrence of shift of the central position and the like of the substrate before and after the rotation. Therefore, the TIS measurement of the alignment detection system can be performed in a short time and with high accuracy.

Here, “substantially 180°” includes, for example, an angle of 180°±about 10 minutes (about a few mrad) as well as precise 180°. And, since the stage holder is “capable of rotating through substantially 180°”, it naturally includes a case where the substrate holder can rotate through an angle exceeding substantially 180°. Herein, the phrase “capable of rotating through substantially 180°” has such meaning.

According to a second aspect of the present invention, there is provided a first measurement unit that measures the detection shift caused by the mark detection system, which optically detects the mark formed on the substrate, the measurement unit comprising a stage that moves within a two-dimensional plane; a positional detection system that detects the position of the stage; a substrate holder, which is mounted on the stage, that holds the substrate, is capable of rotating through substantially 180° around the predetermined rotation axis orthogonal to the two-dimensional plane, and have at least one fiducial mark arranged on a portion outside a holding plane for the substrate; a drive unit which can be mechanically connected to the substrate holder, and drives and rotates the substrate holder; a first detection control system that detects positional information of at least one particular fiducial mark out of the fiducial mark or marks and positional information of at least one selected alignment mark on the substrate by using the mark detection system and the positional detection system in a first state where the orientation of the substrate holder is set to a predetermined direction; a second detection control system that detects the positional information of each of the marks, whose positional information was detected in the first state, by using the mark detection system and the positional detection system in a second state where the substrate holder has been rotated through 180° from the first state via the drive unit; and an arithmetical unit which is electrically connected to said first and second detection control systems, and calculates a detection shift caused by said mark detection system by using the detection results of said first detection control system and said second detection control system.

Here, the “detection shift caused by the mark detection system” means the detection shift inherent to the mark detection system, most of which is the aberration amount of the optical system constituting the mark detection system, and which also includes the detection shift caused by the process of the substrate on which the marks to be detected are formed, such as the foregoing TIS.

With this measurement unit, the positional information of at least one particular mark out of the fiducial marks formed on the substrate holder and the positional information of at least one selected alignment mark on the substrate, which is mounted on the substrate holder, are detected by the first detection control system using the mark detection system and the positional detection system in the first state where the orientation of the substrate holder is set to the predetermined direction on the stage. Next, by the second detection control system, the substrate holder is rotated through 180° from the first state via the drive unit, and in a second state, the positional information of each mark, whose positional information was detected in the first state, is detected using the mark detection system and the positional detection system. Then, the arithmetical unit calculates the detection shift caused by the mark detection system, using the detection results of the first and second detection control systems. According to the present invention, information regarding the positional relation between an alignment mark and a fiducial mark is obtained in the first and second states severally, and a predetermined computation is performed using the information of the positional relation between both the marks. Thus, the detection shift caused by the mark detection system can be calculated easily and with good accuracy. The reasons are as follows.

Despite that the positional relation between the fiducial mark and the alignment mark does not actually change between the first and second states as long as the position of the substrate with respect to the substrate holder does not change, obtained positional relations between both the marks are different. This is because information of each of the positional relations includes the detection shift caused by the mark detection system. Accordingly, by performing a predetermined computation based on the information of the positional relation between both the marks in the first state and the information of the positional relation between both the marks in the second state, the detection shift caused by the mark detection system can be detected easily and with good accuracy. Further, in this case, since the fiducial mark is formed on the substrate holder, measurement of the foregoing detection shift can be performed on any substrate mounted on the holder. Thus, the detection shift of the mark detection system for a mark on a substrate actually used in exposure can be measured.

In this case, the detection results of the first detection control system and the second detection control system may produce the positional information of one fiducial mark and of one particular alignment mark on the substrate. In such a case, since the fiducial mark and the alignment mark are detected one mark at a time in the first and second states, calculation of the detection shift caused by the mark detection system can be performed in a short time.

In the first measurement unit of the present invention, the detection results of the first detection control system and the second detection control system may severally include the positional information of a plurality of same fiducial marks, and for each of said first and second states, the arithmetical unit may statistically processes positional information of the plurality of fiducial marks to calculate the information regarding the position of the substrate holder in the state, and then calculate the detection shift caused by the mark detection system by using the calculation results. In such a case, the positional information of the plurality of same fiducial marks detected in each of the first and the second states is statistically processed to calculate the information regarding the position of the substrate holder in the state. Therefore, not only more accurate information regarding the position of the substrate holder is calculated, but also more accurate calculation of the detection shift caused by the mark detection system is enabled.

In the first measurement unit of the present invention, the detection results of the first detection control system and the second detection control system may severally include the positional information of a plurality of same alignment marks, and for each of said first and second states, the arithmetical unit may statistically processes positional information of the plurality of alignment marks to calculate the information regarding the position of the substrate holder in the state, and then calculate the detection shift caused by the mark detection system by using the calculation results. In such a case, the positional information of the plurality of same alignment marks detected in each of the first and the second states is statistically processed to calculate the information regarding the position of the substrate in the state. Therefore, not only more accurate information regarding the position of the substrate is calculated, but also more accurate calculation of the detection shift caused by the mark detection system is enabled.

According to a third aspect of the present invention, there is provided a first exposure apparatus that exposes the substrate with an energy beam to form a predetermined pattern on the substrate, comprising the measurement unit of the present invention; and a control unit that controls the position of the stage upon exposure so as to correct the detection shift caused by the mark detection system, the detection shift being measured by the measurement unit.

With this exposure apparatus, the control unit controls the position of the stage upon exposure so as to correct for the detection shift caused by the mark detection system, which has been measured by the first measurement unit of the present invention. Thus, exposure of the substrate can be performed with high accuracy.

According to a fourth aspect of the present invention, there is provided a second measurement unit comprising a stage which moves along a two-dimensional plane; a position detection system which detects position of said stage in said two-dimensional plane; a mark detection system which detects a mark present on said stage; a substrate holder which is mounted on said stage, is capable of rotating through substantially 180° about a predetermined rotation axis perpendicular to said two-dimensional plane with being holding a substrate thereon, and of which a plurality of measurement marks are arranged on a face on which said substrate is mounted; a driving unit which is mechanically connected to said substrate holder and drives said substrate holder to rotate; a first detection control system which detects position information of said plurality of measurement marks by use of said position detection system and said mark detection system in a first state where the orientation of said substrate holder is set to a predetermined direction; a second detection control system which, after having rotated said substrate holder through substantially 180° from said first state via said driving unit to be in a second state, detects position information of said plurality of measurement marks by use of said position detection system and said mark detection system in said second state; and a first computing unit which is connected electrically to said first and second detection control systems and, based on detecting results of said first and second detection control systems, calculates a deformation amount of said substrate holder due to a change from said first state to said second state.

According to this, a first detection control system detects position information of said plurality of measurement marks, which are provided on a face of a substrate holder mounted on a stage on which face a substrate is mounted, by use of a position detection system for detecting the stage's position and a mark detection system for detecting a mark present on the stage in a first state where the orientation of said substrate holder is set to a predetermined direction, the face being called “substrate mount face” as needed, and a second detection control system detects position information of said plurality of measurement marks provided on the substrate mount face by use of said position detection system and said mark detection system in a second state where said substrate holder has been rotated through substantially 180° from said first state; And a first computing unit, based on detecting results of said first and second detection control systems, calculates a deformation amount of said substrate holder due to a change from said first state to said second state. In this case, a deformation amount of said substrate holder can be calculated easily and relatively accurately by use of only the result of detecting position information of said plurality of measurement marks in said first state and in said second state where said substrate holder has been rotated through substantially 180° from said first state. The reason for that is as follws.

That is, if there is no deformation cause, positional relations between the plurality of measurement marks arranged on the substrate mount face should not change between the first state and the second state, where the wafer holder has been rotated through 180° from the first state. Therefore, when deformation of the wafer holder occurs due to the rotation thereof, positional relations between the plurality of measurement marks change according to the deformation. Therefore, by performing a predetermined computation based on position information of the plurality of measurement marks in the first state as a reference and position information of the plurality of measurement marks affected by deformation of the wafer holder in the second state, the deformation of the wafer holder can be calculated easily and accurately. In this case, the measurement marks whose position information is to be detected are preferably marks that hardly cause a detection error such as TIS inherent in the mark detection system.

As a result, even when by using, for example, the above-mentioned substrate holder capable of rotating through substantially 180° and a tool wafer, TIS of the mark detection system is measured like in the prior art, by, e.g., correcting for the measured TIS with the deformation of the substrate holder obtained according to this invention, the detection error inherent in the mark detection system can be detected very accurately and in a short time.

In this case, said plurality of measurement marks may include a first mark provided within a mount area of said substrate holder on which said substrate is mounted and a second mark formed outside said mount area of said substrate holder.

In this case, said first mark may be formed on said substrate mounted on said mount area.

In this case, said substrate may be an exclusively-for-measurement substrate of which the upper face is not coated with a photosensitive material.

In the second measurement unit according to this invention, when said plurality of measurement marks include said first mark and second mark, said first detection control system may detect position information of said first mark and said second mark in said first state; said second detection control system may detect in said second state position information of said marks, of which said position information has been detected in said first state, and said first computing unit may compute information on distance in said first state between said first mark and said second mark and information on distance in said second state between said marks, and calculates said deformation amount of said substrate holder based on the computing result.

In the second measurement unit according to this invention, said first detection control system may detect in said first state position information of a plurality of measurement marks including a mark provided within a mount area of said substrate holder on which said substrate is mounted; said second detection control system may detect in said second state position information of a plurality of measurement marks including a mark provided within a mount area of said substrate holder on which said substrate is mounted, and said first computing unit may calculate said deformation amount of said substrate holder by use of first deformation information obtained by statistically processing position information of said plurality of measurement marks, detected by said first detection control system, and second deformation information obtained by statistically processing position information of said plurality of measurement marks, detected by said second detection control system.

In this case, while said plurality of measurement marks detected by said second detection control system may be different marks from said plurality of measurement marks detected by said first detection control system, said plurality of measurement marks detected by said second detection control system are preferably same marks as said plurality of measurement marks detected by said first detection control system.

In the second measurement unit according to this invention, said plurality of measurement marks may be arranged within a mount area of said substrate holder on which said substrate is mounted.

In this case, said plurality of measurement marks may be formed on said substrate mounted on said mount area, or said plurality of measurement marks may be formed within said mount area of said substrate holder. In the former case, said substrate may be an exclusively-for-measurement substrate of which the upper face is not coated with a photosensitive material.

In the second measurement unit according to this invention, each of said first detection control system and said second detection control system may detect position information of a respective plurality of measurement marks, and said first computing unit may calculate said deformation amount of said substrate holder by use of first deformation information obtained by statistically processing position information of said plurality of measurement marks, detected by said first detection control system, and second deformation information obtained by statistically processing position information of said plurality of measurement marks, detected by said second detection control system.

In this case, while said plurality of measurement marks detected by said second detection control system may be different marks from said plurality of measurement marks detected by said first detection control system, said plurality of measurement marks detected by said second detection control system are preferably same marks as said plurality of measurement marks detected by said first detection control system.

The second measurement unit according to this invention, when said plurality of measurement marks include a substrate mark formed on said substrate mounted on said substrate holder and a fiducial mark formed outside a mount area of said substrate holder on which said substrate is mounted, may further comprise a storage unit which stores a deformation amount of said substrate holder computed by said first computing unit; a third detection control system which detects position information of said substrate mark and said fiducial mark by use of said position detection system and said mark detection system in a third state where the orientation of said substrate holder is set to be a same as in said first state; a fourth detection control system which, after having rotated said substrate holder through substantially 180° from said third state via said driving unit to be in a fourth state, detects position information of said marks, of which said position information has been detected in said third state, by use of said position detection system and said mark detection system in said fourth state; and a second computing unit which is connected electrically to said third and fourth detection control systems and, based on detecting results of said third and fourth detection control systems, calculates a seeming detection shift due to said mark detection system and then calculates a real detection shift due to said mark detection system based on the calculating result and said deformation amount stored in said storage unit.

Here, the “real detection shift due to the mark detection system” means a detection shift inherent in the mark detection system including aberrations due to an optical system constituting the mark detection system and, when the mark to be detected is formed on a substrate, a detection shift due to the process that the substrate is subject to. That is, the above-mentioned TIS is the real detection shift due to the mark detection system. The fiducial mark is a mark that hardly causes a detection error in the mark detection system and that is a reference for position measurement.

In this case, a third detection control system detects position information of said substrate mark formed on a substrate and said fiducial mark by use of said position detection system and said mark detection system in a third state where the orientation of said substrate holder is set to be a same as in said first state; a fourth detection control system detects position information of said marks, of which said position information has been detected by said third detection control system, in a fourth state where said substrate holder has been rotated through substantially 180° from said third state, and a second computing unit calculates the real detection shift due to said mark detection system based on a seeming detection shift due to said mark detection system calculated from the detecting results and based on said deformation amount stored in said storage unit. That is, by performing a predetermined computation based on position information of the substrate mark and fiducial mark obtained in the third and fourth states and deformation amount of the substrate holder obtained beforehand, the real detection shift due to said mark detection system can be calculated easily and accurately. The reason for that is as follows.

That is, if there is no deformation cause, positional relation between the substrate mark and the fiducial mark should not change between the third state and the fourth state, where the substrate holder has been rotated through 180° from the third state. Therefore, the typical causes that positional relation between the substrate mark and the fiducial mark changes between the third state and the fourth state are deformation of the holder and the detection error of the mark detection system upon measuring the substrate mark. Therefore, by subtracting the deformation amount of the substrate holder due to the change from the third (or first) state to the fourth (or second) state stored in the storage unit from the change between the third and fourth states (a seeming detection shift due to the mark detection system), the real detection shift due to the mark detection system can be calculated easily and accurately.

According to a fifth aspect of the present invention, there is provided a second exposure apparatus which exposes a substrate with an energy beam to form a predetermined pattern on said substrate, said exposure apparatus comprising the measurement unit according to this invention; and a controller which controls position of said stage upon exposure so as to correct for a real detection shift due to said mark detection system measured by said measurement unit.

According to this, a controller controls position of said stage upon exposure for forming a given pattern on a substrate so as to correct for a real detection shift due to said mark detection system measured easily and accurately by said measurement unit. Therefore, patterns can be accurately formed on a substrate while accurately controlling position of said stage upon exposure based on the result of the mark detection system detecting positions of marks on the substrate.

According to a sixth aspect of the present invention, there is provided a first measurement method that measures aberrations caused by a mark detection system, which optically detects marks formed on a substrate, the method comprising a first step of mounting the substrate, on which at least one alignment mark is formed, on a substrate holder where at least one fiducial mark is formed in the vicinity of its peripheral portion; a second step of detecting at least one particular fiducial mark out of the fiducial mark or marks and at least one selected alignment mark on the substrate by using the mark detection system in a first state where the orientation of the substrate holder is set to a predetermined direction, and obtaining the positional information of each mark to be detected based on the detection results and a position of the substrate holder when each mark is detected; a third step of detecting each mark to be detected by using the mark detection system in a second state where the substrate holder has been rotated through 180° from the first state around a predetermined rotation axis, which is substantially orthogonal to a mounting plane for the substrate, and obtaining the positional information of each mark to be detected based on the detection result and a position of the substrate holder when each mark is detected; and a fourth step of calculating the detection shift caused by the mark detection system by using the positional information of each mark to be detected, which has been obtained in the second and third steps.

According to this method, in the first step, the substrate, on which at least one alignment mark is formed, is mounted on the substrate holder where at least one fiducial mark is formed in the vicinity of its peripheral portion. And, in the second step, at least one particular fiducial mark out of the fiducial mark and at least one selected alignment mark on the substrate are detected by using the mark detection system in the first state where the orientation of the substrate holder is set to the predetermined direction, and the positional information of each mark to be detected is obtained based on the detection results and the position of the substrate holder when each mark is detected. Further, in the third step, each mark to be detected is detected by using the mark detection system in the second state where the substrate holder has been rotated through 180° from the first state around the predetermined rotation axis, which is substantially orthogonal to a mounting plane for the substrate, and the positional information of each mark to be detected is obtained based on the detection result and the position of the substrate holder when each mark is detected. And then, in the fourth step, the detection shift caused by the mark detection system is calculated by using the positional information of each mark to be detected, which has been obtained in the second and third steps. In this case as well, the detection shift caused by the mark detection system can be obtained simply and with high accuracy for the same reason as in the first measurement unit of the present invention.

In this case, the positional information of one fiducial mark and of one particular alignment mark on the substrate may be obtained in the second and third steps. In such a case, calculation of the detection shift caused by the mark detection system can be performed in a short time, since only one fiducial mark and one alignment mark are detected in each of the first and second states.

In the first measurement method of the present invention, the positional information obtained in the second step and the positional information obtained in the third step may severally include the positional information of a plurality of same fiducial marks, and for each of said first and second states, the fourth step may statistically process positional information of the plurality of fiducial marks to calculate the information regarding the position of the substrate holder in the state, and then calculate the detection shift caused by the mark detection system by using the calculation results. In such a case, the positional information of the plurality of same fiducial marks detected in each of the first and second states is statistically processed to calculate the information regarding the position of the substrate holder in the state. Therefore, not only more accurate information regarding the position of the substrate holder can be calculated, but also more accurate detection shift caused by the mark detection system can be calculated.

In this case, the information regarding the position obtained as the result of the statistic processing can contain an offset in a coordinate axis direction on an orthogonal coordinate system that defines the movement of the substrate holder.

In the first measurement method of the present invention, the positional information obtained in the second step and the positional information obtained in the third step may severally include the positional information of a plurality of same alignment marks, and for each of said first and second states, the fourth step may statistically process positional information of the plurality of alignment marks to calculate the information regarding the position of the substrate in the state, and then calculate the detection shift caused by the mark detection system by using the calculation results. In such a case, the positional information of the plurality of same alignment marks detected in each of the first and second states is statistically processed to calculate the information regarding the position of the substrate in the state. Therefore, not only more accurate information regarding the position of the substrate can be calculated, but also more accurate detection shift caused by the mark detection system can be calculated.

In this case, the information regarding the position of the substrate can be obtained based on the mean value of pieces of positional information of the plurality of alignment marks. Moreover, the information regarding the position of the substrate can contain an offset in a coordinate axis direction on an orthogonal coordinate system that defines the movement of the substrate holder.

According to a seventh aspect of the present invention, there is provided a first exposure method that exposes a substrate with an energy beam to form a predetermined pattern on the substrate, comprising a step of measuring the detection shift caused by the mark detection system by the first measurement method of the present invention; and a step of controlling the position of the substrate holder upon exposure so as to correct for the detection shift caused by the mark detection system, which sift has been measured by the measurement method.

According to this, because controlling the position of the substrate holder upon exposure so as to correct for the detection shift due to the mark detection system, which sift has been measured by the first measurement method of this invention, exposure of a substrate can be performed very accurately.

According to an eighth aspect of the present invention, there is provided a second measurement method comprising a first step of detecting, by use of a mark detection system, a plurality of measurement marks provided on a face of a substrate holder on which a substrate is mounted in a first state where the orientation of said substrate holder is set to a predetermined direction, said substrate holder being capable of holding said substrate, and obtaining position information of said plurality of measurement marks based on the detecting result and positions of said substrate holder each of which has been detected upon detection of a corresponding mark of said plurality of measurement marks; a second step of detecting, by use of said mark detection system, said plurality of measurement marks in a second state where said substrate holder has been rotated through substantially 180° from said first state about a predetermined rotation axis substantially perpendicular to said substrate-mount face, and obtaining position information of said plurality of measurement marks based on the detecting result and positions of said substrate holder each of which has been detected upon detection of a corresponding mark of said plurality of measurement marks; and a third step of calculating a deformation amount of said substrate holder due to a change from said first state to said second state by use of position information of said plurality of measurement marks obtained in said first and second steps.

According to this, in a first step, a plurality of measurement marks provided on the substrate mount face of a substrate holder are detected by use of a mark detection system in a first state where the orientation of said substrate holder is set to a predetermined direction, and position information of said plurality of measurement marks is obtained based on the detecting result and positions of said substrate holder each of which has been detected upon detection of a corresponding mark of said plurality of measurement marks; in a second step, position information of said plurality of measurement marks is detected in a second state where said substrate holder has been rotated through substantially 180° from said first state, in the same way as in the first step; and in a third step, a deformation amount of said substrate holder due to a change from said first state to said second state is calculated by use of position information obtained in said first and second steps of said plurality of measurement marks. Therefore, for the same reason as described with the second measurement unit, the deformation amount of the substrate holder can be calculated easily and accurately. As a result, when TIS measurement of the mark detection system is performed using the substrate holder in the same procedure as in the prior art, by, e.g., correcting the measuring result with the deformation amount of the substrate holder obtained according to this invention, the detection error inherent in the mark detection system can be detected very accurately.

In this case, said plurality of measurement marks may include a first mark formed on a substrate mounted on said substrate holder and a second mark formed outside a mount area of said substrate holder on which said substrate is mounted.

In this case, in said first step, position information of said first mark and said second mark may be detected in said first state; in said second step, position information of said marks, of which said position information has been detected in said first state, may be detected in said second state, and in said third step, information on distance in said first state between said first mark and said second mark and information on distance in said second state between said marks may be computed, and said deformation amount of said substrate holder is calculated based on the computing result.

In the second measurement method according to this invention, in said first step, position information of a plurality of measurement marks including a mark formed on a substrate mounted on said substrate holder may be detected in said first state; in said second step, position information of said marks, of which said position information has been detected in said first state, may be detected in said second state, and in said third step, said deformation amount of said substrate holder may be calculated by use of first deformation information obtained by statistically processing position information of said plurality of measurement marks, detected in said first state, and second deformation information obtained by statistically processing position information of said marks, detected in said second state.

In the second measurement method according to this invention, in said first step and in said second step, position information of a same plurality of measurement marks formed on said substrate mounted on said substrate holder may be obtained, and in said third step, said deformation amount of said substrate holder may be calculated by use of first deformation information obtained by statistically processing position information of said plurality of measurement marks, obtained in said first step, and second deformation information obtained by statistically processing position information of said plurality of measurement marks, obtained in said second step.

The second measurement method according to this invention may further comprise a fourth step of detecting, by use of said mark detection system in a third state where the orientation of said substrate holder is set to be a same as in said first state, a substrate mark formed on said substrate mounted on said substrate holder and a fiducial mark formed outside a mount area of said substrate holder on which said substrate is mounted, said substrate mark and said fiducial mark being included in said plurality of measurement marks, and obtaining position information of said marks based on the detecting result and positions of said substrate holder each of which has been detected upon detection of a corresponding mark of said marks; a fifth step of detecting positions of said marks, of which said position information has been detected in said third state, by use of said mark detection system in a fourth state where said substrate holder has been rotated through substantially 180° from said third state and obtaining position information of said marks based on the detecting result and positions of said substrate holder each of which has been detected upon detection of a corresponding mark of said marks; and a sixth step of calculating a seeming detection shift due to said mark detection system based on detecting results of said fourth step and said fifth step, and then calculating a real detection shift due to said mark detection system based on the calculating result and said deformation amount calculated in said calculating a deformation amount. In this case, by performing a predetermined computation based on position information of the substrate mark and fiducial mark obtained in the third and fourth states and the deformation amount of the substrate holder, for the same reason as with the measurement unit of claim 6 the real detection shift due to the mark detection system can be calculated easily and accurately.

According to a ninth aspect of the present invention, there is provided a second exposure method with which to expose a substrate to an energy beam to form a predetermined pattern on said substrate, said exposure method comprising measuring a real detection shift due to said mark detection system according to the second measurement method; and controlling position of said stage upon exposure so as to correct for said measured, real detection shift due to said mark detection system.

According to this, because controlling position of said stage upon exposure for forming a given pattern on a substrate so as to correct for a real detection shift due to said mark detection system measured easily and accurately, patterns can be accurately formed on the substrate.

Moreover, by performing exposure by use of either of the first and second exposure methods of this invention in a lithography process, patterns can be accurately formed on a substrate, and more highly integrated micro-devices can be manufactured with high yield. Therefore, according to another aspect of the present invention, there is provided a device manufacturing method using either of the first and second exposure methods of this invention.

### BRIEF DESCRIPTION OF THE DRAWINGS

In the accompanying drawings,

FIG. 1 is a view schematically showing the constitution of an exposure apparatus according to a first embodiment;

FIG. 2 is a view showing a partial section through a Z-tilt stage with a wafer holder;

FIGS. 3A and 3B each are a magnified view of an example of a fiducial mark formed on a fiducial plate for measurement;

FIGS. 4A and 4B are views for explaining the method of detecting TIS of an alignment detection system of the exposure apparatus according to the first embodiment;

FIGS. 5A and 5B are views specifically showing examples of the order in which measurement marks (or alignment marks) and fiducial marks are measured;

FIGS. 6A and 6B are views for explaining the method of measuring the holder deformation amount in an exposure apparatus according to a second embodiment;

FIG. 7 is a flow chart for explaining an embodiment of the method of this invention for manufacturing devices; and

FIG. 8 is a flow chart showing an example of the process in step 204 of FIG. 7.

### DESCRIPTION OF THE PREFERRED EMBODIMENTS

<<A First Embodiment>>

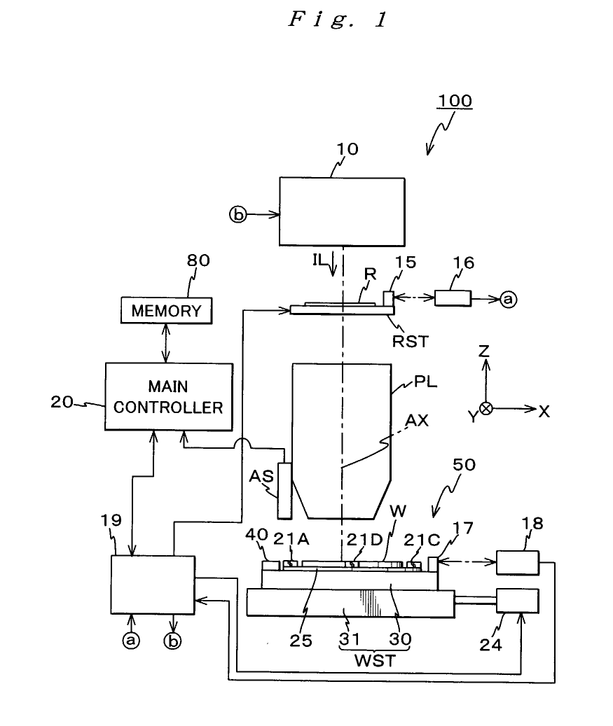

In the following, a first embodiment of the present invention will be described on the basis of FIGS. 1 to 5B.

FIG. 1 shows a schematic structure of an exposure apparatus 100 according to the embodiment. The exposure apparatus 100 is a projection exposure apparatus of a step-and-scan method. The exposure apparatus 100 comprises an illumination system 10, a reticle stage RST holding a reticle R, a projection optical system PL, a stage unit 50 where a wafer W as a substrate is mounted, a main controller 20 generally controlling the entire apparatus, and the like.

The illumination system 10, as disclosed in Japanese Patent Laid-Open 10-112433, 6-0349701 and corresponding U.S. Pat. No. 5,534,970 and the like, for example, is constituted by including: an illumination uniformity optical system having a light source, fly-eye lens or a rod integrator (an internal reflection integrator) and the like; a relay lens; a variable ND filter; a reticle blind; a dichroic mirror; and the like (none are shown). The disclosure cited in the foregoing United States Patent is fully incorporated herein by reference.

In the illumination system 10, a slit-shaped illumination area portion, which is defined by the reticle blind, on the reticle R where a circuit pattern and the like are drawn is illuminated with substantially uniform illumination by illumination light IL as the energy beam. Herein, far-ultraviolet light such as a KrF excimer laser beam (wavelength of 248 nm), an ArF excimer laser beam (wavelength of 193 nm) or vacuum ultraviolet light such as an F₂ laser beam (wavelength of 157 nm) is used as the illumination light IL. Bright rays (a g-ray, an i-ray and the like) in a ultraviolet region from an ultra high-pressure mercury lamp also can be used as the illumination light IL.

The reticle R is fixed on the reticle stage RST, for example, by vacuum chucking. The reticle stage RST can be finely driven for positioning the reticle R within an XY plane perpendicular to the optical axis of the illumination system 10 (which coincides with an optical axis AX of the projection optical system PL, to be described later) by a reticle stage drive section (not shown) including a linear motor or the like, for example, and can be driven in a predetermined scanning direction (a Y direction in this case) with a specified scanning velocity.

The position of the reticle stage RST within a stage-moving plane is continuously detected by a reticle laser interferometer (hereinafter, referred to as a “reticle interferometer”) 16 via a moving mirror 15 with a resolving power of, for example, about 0.5 to 1 nm. The positional information of the reticle stage RST from the reticle interferometer 16 is supplied to a stage control system 19 and also to the main controller 20 via the stage control system. The stage control system 19 drives and controls the reticle stage RST via a reticle stage drive section (illustration omitted) in accordance with an instruction from the main controller 20 based on the positional information of the reticle stage RST.

A pair of reticle alignment systems are arranged above the reticle R (not shown). Each of the reticle alignment systems is constituted by including: an episcopic illumination system that illuminates the mark to be detected with illumination light having the same wavelength as the illumination light IL; and a reticle alignment detection system that picks up an image of the mark to be detected. The reticle alignment detection system includes an imaging optical system and a pick-up device, and the imaging result by the reticle alignment detection system is supplied to the main controller 20. In this case, deflecting mirrors (not shown) that guide detection light from the reticle R to the reticle alignment system are arranged to be freely movable. When an exposure sequence starts, each deflecting mirror is withdrawn out of the optical path of the illumination light IL integrally with he reticle alignment system, by an instruction from the main control section 20.

The projection optical system PL is arranged at the lower part of FIG. 1, and the orientation of its optical axis AX is set to be a Z-axis direction. For example, a refraction optical system telecentric on both sides with a predetermined reduction magnification (for example, ⅕ or ¼) is used as the projection optical system PL. Accordingly, the illumination area of the reticle R is illuminated by the illumination light IL from the illumination system 10, the reduced image (an inverted image) of the circuit pattern of the reticle R in the illumination area is formed on the wafer W of which the surface is coated with a resist (photosensitive material).

The stage unit 50 comprises: a wafer stage WST as the stage; a wafer holder 25 as the substrate holder; and a wafer stage drive section 24 that drives the wafer stage WST and the wafer holder 25. The wafer stage WST is arranged on a base (not shown) and below the projection optical system PL at the lower part of FIG. 1. The wafer stage WST comprises: an XY stage 31 driven in an XY direction by the linear motor or the like (not shown), which constitutes the wafer stage drive section; and a Z-tilt stage 30 mounted on the XY stage 31 and finely driven by a Z-tilt drive mechanism (not shown) in a Z-axis direction and a tilted direction relative to the XY plane. Moreover, the wafer holder 25 is provided on the Z-tilt stage 30 and designed to hold the wafer by chucking.

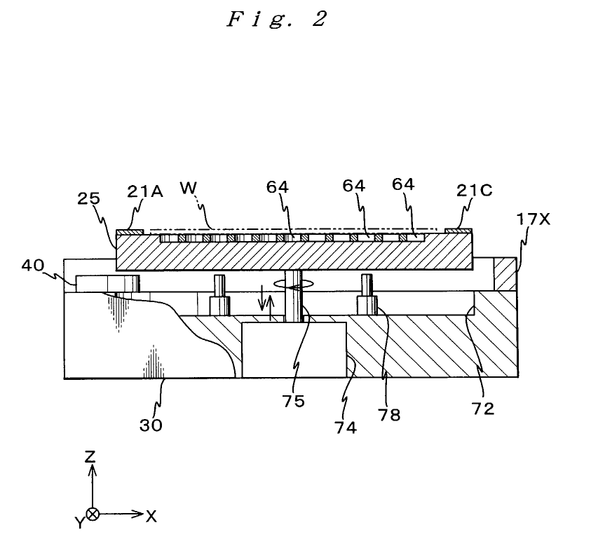

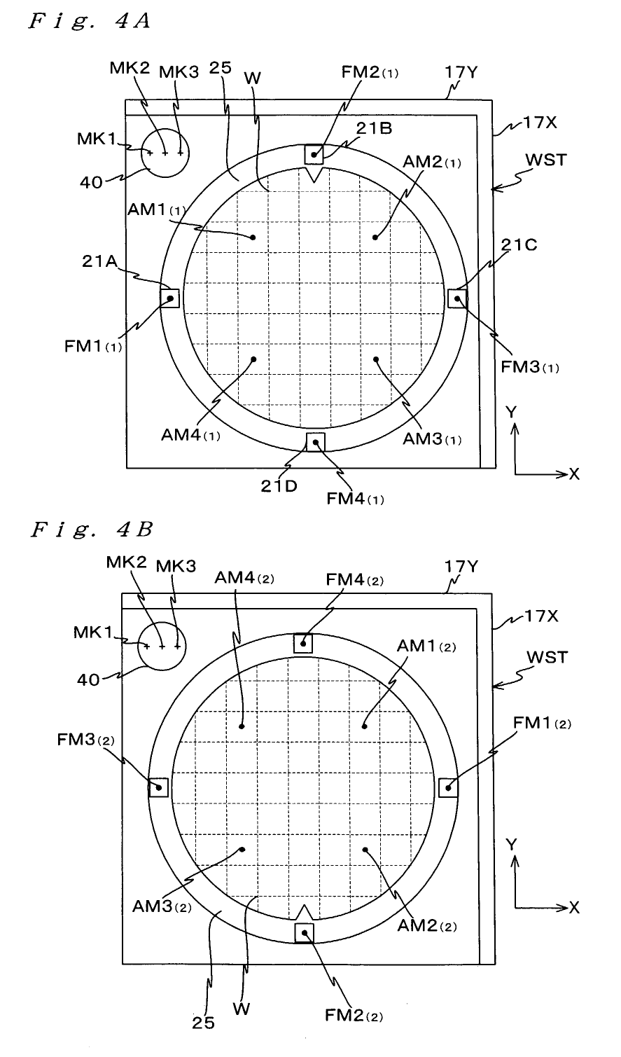

The wafer holder 25 has a discoidal shape as can be recognized when seeing FIG. 2 showing a partial section through the wafer holder 25 with the Z-tilt stage 30, FIG. 4A and the like. A plurality of concentric grooves 64 having different diameters are formed on the upper surface of the wafer holder 25 as shown in FIG. 2. A number of suction holes (not shown) are provided in the grooves 64, and the wafer is held on the wafer holder 25 by vacuum chucking of a vacuum pump (not shown) via the suction holes.

Further, a round hole 72 with which the lower half portion of the wafer holder 25 can engage is formed on the Z-tilt stage 30, as shown in FIG. 2. The wafer holder 25 is designed to be fixed on the Z-tilt stage 30 by the vacuum chucking by a vacuum chucking mechanism (not shown) in the state where the lower half portion engages with the round hole 72.

At the bottom part of the Z-tilt stage 30, a vertical-movement-and-rotation mechanism 74 as a driving unit is embedded in a position corresponding to the central portion of the inner bottom surface of the round hole 72. The vertical-movement-and-rotation mechanism 74 includes a motor and the like (not shown), and is a mechanism that moves vertically and rotates a drive shaft 75 through substantially 180°, one end of which is fixed at the bottom surface of the wafer holder 25. The vertical-movement-and-rotation mechanism 74 constitutes a part of the wafer stage drive section in FIG. 1, and is controlled by the stage control system 19 in FIG. 1.

Furthermore, three vertical movement pins (center-up) 78 driven by a drive mechanism constituting the wafer stage drive section 24 are provided at the inner bottom surface of the round hole 72. In the state where the wafer holder 25 is fixed on the Z-tilt stage 30 by vacuum chucking, each head of the vertical movement pins 78 can stick out and retract from the upper surface of the wafer holder 25 via round holes (not shown) severally formed at predetermined positions, of the wafer holder 25, each opposite a respective vertical movement pin 78. Accordingly, the three vertical movement pins 78 can support or move vertically a wafer W at three points while replacing the wafer.

On the upper surface of the wafer holder 25, four fiducial plates 21A, 21B, 21C and 21D for measurement are arranged in a predetermined positional relation on a peripheral portion of the wafer W, specifically at the position of each apex of a square, as shown in FIG. 4A. The upper surface of the four fiducial plates 21A, 21B, 21C and 21D for measurement is set to be at a height same as the surface of the wafer W mounted on the wafer holder 25.

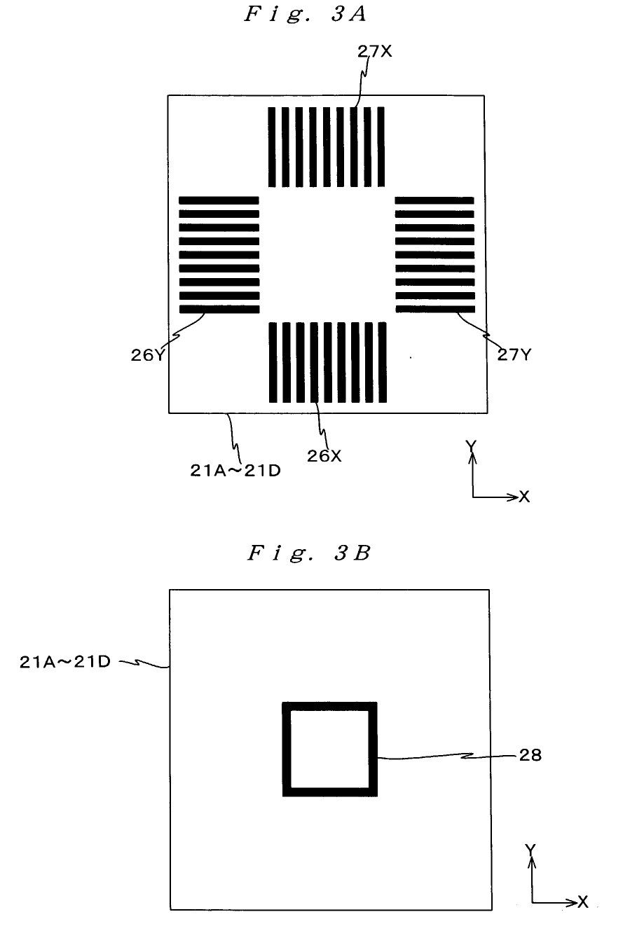

Fiducial marks FM1, FM2, FM3 and FM4 are respectively formed on the upper surface of the fiducial plates 21A, 21B, 21C and 21D. As shown in the magnified plan view of FIG. 3A, each of the fiducial marks FM1, FM2, FM3 and FM4 includes a X-axis mark 26X that consist of, for example, 6 μm line-and-space (hereinafter, L/S for short) marks arranged in the X-axis direction; a Y-axis mark 26Y that consist of, for example, 6 μm L/S marks arranged in the Y-axis direction; a segment mark 27X, in which segments that each consist of, for example, 0.2 μm L/S marks arranged in the X-axis direction and that each have a total width of 6 μm are arranged in the X-axis direction at, for example, a 6 μm pitch; and a segment mark 27Y, in which segments that each consist of, for example, 0.2 μm L/S marks arranged in the Y-axis direction and that each have a total width of 6 μm are arranged in the Y-axis direction at, for example, a 6 μm pitch. Note that at least either one of the X-axis and Y-axis marks (26X and 26Y) and at least either one of the segment marks (27X and 27Y) may be formed on the fiducial plate for measurement. If formation of the X-axis and Y-axis marks (26X and 26Y) with the wide line width of 6 μm is difficult, only the segment marks (27X and 27Y) with the narrow line width may be formed. It is remarked that, not being limited to the above-mentioned mark, various marks such as a box-shaped mark 28 as shown in FIG. 3B can be used as the fiducial mark FMn.

Since the fiducial plates for measurement 21A to 21D are references for the TIS measurement of an alignment detection system AS (described later), the fiducial plates have a shape (pitch, step, composition and the like) hard to be influenced by the aberration such that the measurement result does not fluctuate due to the optical aberration or the like of the alignment detection system AS.

As shown in FIGS. 1, 2, fiducial mark plate 40 is fixed in the vicinity of the wafer W on the Z-tilt stage 30 constituting the wafer stage WST. The surface of the fiducial plate 40 is set to be at the height same as the surface of the wafer holder 25, and a pair of first fiducial marks MK1 and MK3, and a second fiducial mark MK2 are formed on the surface of the fiducial plate 40 in a predetermined positional relation as shown in FIG. 4A.

Referring back to FIG. 1, the XY stage 31 is constituted to be movable in a non-scanning direction (the X-axis direction) orthogonal to a scanning direction (the Y-axis direction) such that a plurality of shot areas on the wafer W are positioned in an exposure area conjugate to the illumination area. By using the XY stage 31 a step-and-scan operation is performed where a scanning exposure operation to each shot area on the wafer W and an operation of moving a next shot to a scanning starting position (acceleration start position) for exposure are repeated.

The position of the wafer stage WST within the XY plane (including rotation about the Z-axis (θ_{z} rotation)) is continuously detected by a wafer laser interferometer system 18 as a position detection system with the resolving power of, for example, about 0.5 to 1 nm via a movable mirror 17 provided on the upper surface of the Z-tilt stage 30. Herein, in an actual constitution, a Y movable mirror 17Y having a reflection plane orthogonal to the scanning direction (the X-axis direction) and an X movable mirror 17X having a reflection plane orthogonal to the non-scanning direction (the Y-axis direction), as shown in FIG. 4A for example, are provided. Corresponding to this, the wafer laser interferometer system 18 is also provided with a Y interferometer radiating an interferometer beam perpendicular to the Y movable mirror and an X interferometer radiating the interferometer beam perpendicular to the X movable mirror 17X. FIG. 1 shows them as the moving mirror 17 and the wafer laser interferometer system 18 representatively. Specifically, in this embodiment, a stationary coordinate system (orthogonal coordinate system) that defines a moving position of the wafer stage WST is defined by a measurement axes of the Y interferometer and the X interferometer of the wafer laser interferometer system 18. In the following, the stationary coordinate system is also referred to as a “stage coordinate system”. Note that at least one of the Y interferometer and the X interferometer of the wafer laser interferometer system 18 is a multi-axes interferometer having a plurality of the measurement axes. This interferometer measures the θ_{z} rotation (yawing) of the wafer stage WST (the Z-tilt stage, more exactly).

The positional information (or the velocity information) of the wafer stage WST in the stage coordinate system is supplied to the stage control system 19 and to the main controller 20 via the stage control system 19. The stage control system 19, in accordance with an instruction of the main controller 20, controls the wafer stage WST based on the foregoing positional information (or the velocity information) of the wafer stage WST via the wafer stage drive section 24. The alignment detection system AS as the mark detection system of an off-axis method is provided on the side surface of the projection optical system PL. As the alignment detection system AS, a field image alignment (FIA) system disclosed in Japanese Patent Laid-Opens 2000-77295, 2-54103 and corresponding U.S. Pat. No. 4,962,318 and the like is used. The disclosure cited in the foregoing United States Patent is fully incorporated herein by reference.

The alignment detection system AS radiates the illumination light (for example, white light) having a predetermined range of wavelength onto the wafer W, has the image of the alignment mark as a mark for the aligning on the wafer W and the image of an index mark on an index plate arranged in a plane conjugate to the wafer W imaged on a receiving plane of a pick-up device (a CCD camera or the like) by an objective lens or the like, and has those images detected. The alignment detection system AS outputs pick-up results of the alignment mark and the first fiducial marks MK1, MK3 on the fiducial mark plate to the main controller 20.

In addition, in the exposure apparatus of this embodiment, the Z-axis direction position of the wafer W, although omitted from the drawing, is measured by a focus sensor that consists of a multi-point focus position detection system disclosed in Japanese Patent Laid-Open 6-283403, and corresponding U.S. Pat. No. 5,448,332 and the like, for example. Output from the focus sensor is supplied to the main controller 20, and the main controller 20 is designed to control the Z-tilt stage 30 to perform a so-called focus leveling control. The disclosure cited in the foregoing United States Patent is fully incorporated herein by reference.

The main controller 20 is constituted by including a microcomputer or a workstation, and generally controls each constituent section of the apparatus.

Next, description will be made for an operation where the exposure apparatus 100 of this embodiment constituted as described above performs exposure processing to a second or later layer for wafers W of a lot (25 pieces for example).

Firstly, the reticle R is loaded on the reticle stage RST by a reticle loader (not shown). After the loading of the reticle R, the main controller 20 measures a reticle alignment and a base line. Specifically, the main controller 20 positions the fiducial mark plate 40 on the wafer stage WST underneath the projection optical system PL via the stage control system 19 and the wafer stage drive section 4, and detects a relative position between a pair of reticle alignment marks on the reticle and a pair of the first fiducial marks MK1 and MK3 for reticle alignment, which correspond to a pair of the reticle alignment marks on the fiducial mark plate 40, by using a reticle alignment system (not shown). Thereafter, the main controller 20 moves the wafer stage WST by a predetermined amount, for example, a design value of the base line amount within the XY plane, and detects the second fiducial mark MK2 for base line measurement on the fiducial mark plate 40 by using the alignment detection system AS. Herein, a phase pattern (a line and space step mark) is used as the second fiducial mark MK2. The main controller 20, as shown in Japanese Patent Laid-Open 2000-77295 for example, in the case of detecting the second fiducial mark MK2 by using the alignment detection system AS, detects the focus position by measuring asymmetry of the image corresponding to the edges of the phase pattern or the difference of image intensities between raised and lower portions of the phase pattern, while moving the wafer holder 25 in the Z-axis direction by a predetermined step via the Z-tilt stage 30, and detects the second fiducial mark MK2 at the Z-position (the best focus state).

The main controller 20 also measures the base line amount (the positional relationship between the projection position of the reticle pattern and the detection center (the index center) of the alignment detection system AS) based on the positional relationship between the detection center of the alignment detection system AS and the second fiducial mark MK2, which relation is obtained from the above detection, the relative position between the reticle alignment marks and the first fiducial mark MK1 and MK3 on the fiducial mark plate 40, which relative position has been measured earlier, and measured values of the wafer interferometer system 18 corresponding thereto.

A wafer processing operation starts at the time when such a series of preparative operations are finished, which will be described below.

Firstly, in the wafer processing operation, a wafer W at the head of a lot (the first wafer in the lot) is loaded on the wafer holder 25 by a wafer loader (not shown) and held by vacuum chucking.

A plurality of the shot areas are arranged on the wafer W in a matrix shape, as shown in FIG. 4A, a chip pattern has been formed on each shot area by exposure, development and the like in previous processes. Each shot area is provided additionally with an alignment mark as a mark for aligning, as representatively shown using alignment marks AM1 to AM4. Although actually each alignment mark is provided on a street line between adjacent shots, hereinafter, each alignment mark is assumed to be provided in a respective shot for the sake of convenience of explanation and illustration.

Moreover, until this time a pre-alignment unit (not shown) has determined the center of the wafer W and performed the rotational alignment thereof. The yawing of the wafer stage WST during the wafer loading is also controlled by the foregoing wafer laser interferometer system 18. Therefore, the wafer W is loaded on the wafer holder 25 in such a direction that the direction of the notch (a V-shaped notch), as seen from the wafer center, substantially coincides with the +Y direction (hereinafter, referred to as a “180° direction”) on the stage coordinate system. The state of the wafer stage WST (the wafer W and the wafer holder 25) after the wafer loading is shown in FIG. 4A, and the state of the wafer W and the wafer holder 25 at this time shall be referred to as a “first state” in the following description.

The measurement of the TIS (tool induced shift) caused by the alignment detection system AS using the wafer holder 25 and the wafer W held on the wafer holder 25 begins here.

Firstly, the control system 20 measures the position coordinates AMn₍₁₎ (AM1₍₁₎, AM2₍₁₎, AM3₍₁₎, AM4₍₁₎) of the alignment marks AMn (n=1,2,3,4) and the position coordinates FMn₍₁₎ (FM1₍₁₎, FM2₍₁₎, FM3₍₁₎, FM4₍₁₎) of the fiducial marks FMn provided on the wafer holder 25.

Specifically, the stage control system 19, while monitoring the measurement value of the wafer laser interferometer system 18, controls the XY two-dimensional movement of the wafer stage WST to sequentially position the fiducial marks and the alignment marks underneath the alignment detection system AS in accordance with instructions from the main controller 20. Upon each positioning, the main controller 20 stores the measurement value of the alignment detection system AS, that is, information on position of the mark to be detected relative to the detection center (the index center) and the corresponding measurement value of the wafer laser interferometer system 18. In this case, the main controller 20, as disclosed in Japanese Patent Laid-Open 2000-77295 for example, detects the focus position by measuring asymmetry, or the difference in image intensity between raised and lower portions, of the image corresponding to the edges of the fiducial mark and the alignment mark, which consist of a phase pattern, while moving the wafer holder 25 in the Z-axis direction by given steps via the Z-tilt stage 30, and detects each mark at that Z-position (the best focus state).

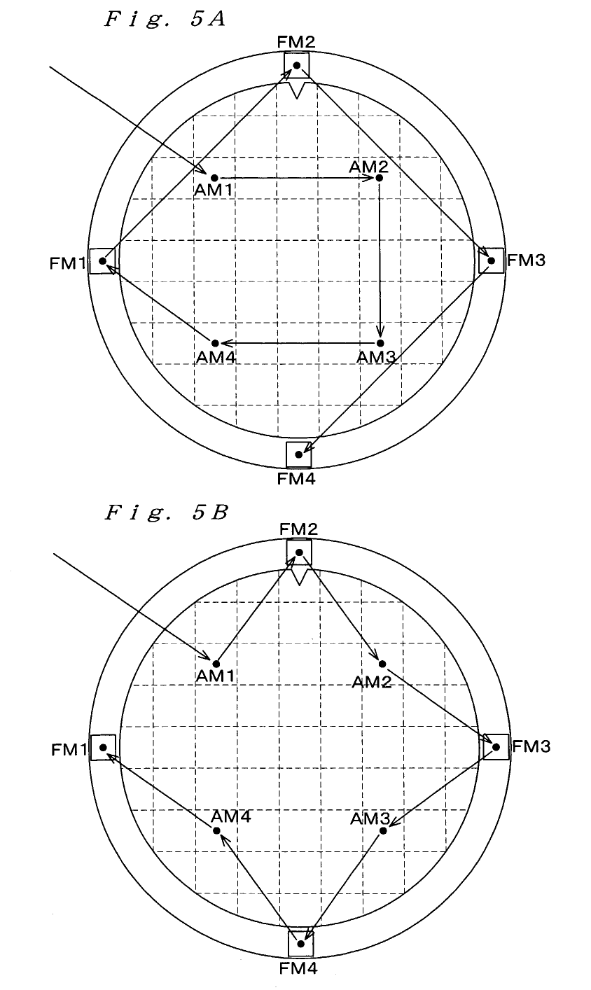

Here, as the measurement order, the fiducial marks FMn may be sequentially measured along a circumference after measuring the alignment marks AMn on the wafer W sequentially along a circumference, as shown in FIG. 5A. Alternatively, to shorten the measurement time and the drive distance of the wafer stage WST, the alignment marks AMn and the fiducial marks FMn may be alternately measured along the circumference, as shown in FIG. 5B.

Next, the main controller 20 calculates the position coordinates AMn₍₁₎ (AM1₍₁₎, AM2₍₁₎, AM3₍₁₎, AM4₍₁₎) in the stage coordinate system of the alignment marks AMn (n=1,2,3,4) and the position coordinates FMn₍₁₎ (FM1₍₁₎, FM2₍₁₎, FM3₍₁₎, FM4₍₁₎) in the stage coordinate system of the fiducial marks FMn provided on the wafer holder 25.

Next, the main controller 20 performs the operation of the following expression (4) to obtain the center position H₁₈₀ of the wafer holder 25 in the first state where the orientation of the wafer W is set to the 180° direction,

H₁₈₀=(FM1₍₁₎+FM2₍₁₎+FM3₍₁₎+FM4₍₁₎)/4. (4)

It is a matter of course that the H₁₈₀ is actually a two-dimensional coordinate value.

Then, the main controller 20 calculates position coordinate W₁₈₀ of a representative point (referred to as a P point for convenience) on the wafer W in the first state based on the following expression (5),

W₁₈₀=(AM1₍₁₎+AM2₍₁₎+AM3₍₁₎+AM4₍₁₎)/4. (5)

It is a matter of course that the W₁₈₀ is actually a two-dimensional coordinate value.

Subsequently, the main controller 20 calculates a distance L₁₈₀x in the X-axis direction and a distance L₁₈₀y in the Y-axis direction between the wafer holder center position and the representative point on the wafer W in the first state, based on the following expressions (6) and (7) respectively, and stores the calculation results into a memory,

L₁₈₀x=W₁₈₀x−H₁₈₀x (6)

L₁₈₀y=W₁₈₀y−H₁₈₀y. (7)

Here, the distance L₁₈₀x in the X-axis direction and the distance L₁₈₀y in the Y-axis direction can also be expressed in the following expressions (6)′ and (7)′ respectively,

$$\begin{matrix}{L}_{180} x = ( W x + {H}_{180} x + T I S x ) - {H}_{180} x \\ = W x + T I S x .\end{matrix} \qquad {( 6 )}^{′}$$

Here, Wx is the X coordinate value (a real value) of the foregoing representative point on the wafer W, which is in a holder coordinate system having its center at the center of the wafer holder and the coordinate axes parallel to those of the stage coordinate system (X, Y). The TISx is an X component of the TIS of the alignment detection system AS,

$$\begin{matrix}{L}_{180} y = ( Wy + {H}_{180} y + T I S y ) - {H}_{180} y \\ = Wy + T I S y .\end{matrix} \qquad {( 7 )}^{′}$$

Here, Wy is the Y coordinate value (a real value), of the foregoing representative point on the wafer W, in the foregoing holder coordinate system. The TISy is a Y component of the TIS of the alignment detection system AS.

When the measurement in the first state is finished as described above, the stage control system 19 controls the vertical-movement-and-rotation mechanism 74 in accordance with instructions from the main controller 20 to elevate the wafer holder 25 to the level shown in FIG. 2 in the state where the wafer W is held by vacuum chucking. Then, after the wafer holder 25 is elevated to a predetermined height, the wafer holder 25 is rotated through 180° by the stage control system 19 via the vertical-movement-and-rotation mechanism 74. Thereafter, the vertical-movement-and-rotation mechanism 74 is controlled by the stage control system 19 to move down the wafer holder 25 to the original height. Note that FIG. 4B shows a state of the wafer W and the wafer holder 25 after the rotation through 180°, and this state will be referred to as a “second state” hereinafter.

In the second state, the wafer W is directed in the 0° direction, which is such a direction that the notch, as seen from the wafer center, faces in the −Y direction. In the same manner as the foregoing case of the first state, the position coordinates AMn₍₂₎ (AM1₍₂₎, AM2₍₂₎, AM3₍₂₎, AM4₍₂₎) regarding the alignment marks AMn (n=1,2,3,4) and the position coordinates FMn₍₂₎ (FM1₍₂₎, FM2₍₂₎, FM3₍₂₎, FM4₍₂₎) regarding the fiducial marks FMn provided on the wafer holder 25 are measured under the control of the main controller 20.

Even in this case, the actually measured value of the alignment mark includes the TIS of the alignment detection system AS. On the other hand, the TIS of the alignment detection system AS included in the measured value of the fiducial mark can be considered as zero.

Next, the main controller 20 performs operation of the following expression (8) to obtain the center position H₀ of the wafer holder 25 in the second state where the orientation of the wafer W is set to the 0° direction,

H₀=(FM1₍₂₎+FM2₍₂₎+FM3₍₂₎+FM4₍₂₎)/4. (8)

It is a matter of course that the H₀ is actually a two-dimensional coordinate value.

Next, the main controller 20 calculates the position coordinate W₀ of the representative point P on the wafer W in the second state based on the following expression (9),

W₀=(AM1₍₂₎+AM2₍₂₎+AM3₍₂₎+AM4₍₂₎)/4. (9)

It is a matter of course that the W₀ is actually a two-dimensional coordinate value.

Subsequently, the main controller 20 calculates a distance L₀x in the X-axis direction and a distance L₀y in the Y-axis direction between the wafer holder center position and the representative point P on the wafer W in the second state, based on the following expressions (10) and (11) respectively, and stores the calculation results in the memory,

L₀x=H₀x−W₀x (10)

L₀y=H₀^{y-W}₀y. (11)

Here, when moving from the “first state” to the “second state”, the wafer holder 25 holding the wafer W is rotated through 180° around the center of the rotation axis (which substantially coincides with the center of the wafer holder) of the wafer holder 25 while maintaining the positional relation between the wafer holder 25 and the wafer, and the position of the alignment detection system AS. Accordingly, the distance L₀x in the X-axis direction and the distance L₀y in the Y-axis direction between the wafer holder center position and the representative point P on the wafer W can be expressed by the following expressions (10)′ and (11)′ respectively,

$$\begin{matrix}{L}_{0} x = {H}_{0} x - ( {H}_{0} x - Wx + T I S x ) \\ = Wx - T I S x\end{matrix} \qquad {( 10 )}^{′}$$

$$\begin{matrix}{L}_{0} y = {H}_{0} y - ( {H}_{0} y - Wy + T I S y ) \\ = Wy - T I S y .\end{matrix} \qquad {( 11 )}^{′}$$

The following expressions for TISx and TISy are obtained from the foregoing expressions (6)′ and (10)′, and (7)′ and (11)′,

TISx=(L₁₈₀x−L₀x)/2 (12)

TISy=(L₁₈₀y−L₀y)/2. (13)

And then, the main controller 20 calculates the X component and the Y component of the TIS of the alignment detection system AS based on the above expressions (12) and (13).

The TIS of the alignment detection system AS obtained as above is subtracted from the position coordinates AMn₍₂₎ (AM1₍₂₎, AM2₍₂₎, AM3₍₂₎, AM4₍₂₎) of the alignment marks, which have been measured in the second state, to obtain real positions AMn₍₀₎ of the alignment marks.

Specifically, the main controller 20 performs a TIS correction on the results of measuring the alignment mark positions based on the following expression (14),

AMn₍₀₎=AMn₍₂₎−TIS. (14)

Fine alignment is performed using an enhanced global alignment (EGA) method, which calculates arrangement coordinates of shot areas on the wafer W based on a statistical computation using a least-squares method disclosed in detail in Japanese Patent Laid-Open 61-44429 and corresponding U.S. Pat. No. 4,780,617 and the like, for example. The disclosure cited in the foregoing United States Patent is fully incorporated herein by reference.

Next, the main controller 20 exposes each shot area on the wafer W with the step-and-scan method. The exposure operation is performed as follows.

Specifically, the stage control system 19, in accordance with an instruction given from the main controller 20 based on the alignment result, controls the wafer stage drive section 24 to move the wafer stage WST to a scanning starting position for exposure of the first shot on the wafer W, while monitoring the measurement values of the X-axis and Y-axis interferometers. At this time, the positional information of the alignment marks is used, which has been corrected for the TIS of the alignment detection system AS, and the scanning starting position is calculated based on the shot arrangement coordinate obtained in accordance with the positional information. Therefore, when the wafer stage WST is moved in accordance with the instruction from the main controller 20, the position of the wafer stage WST (the wafer holder 25) is controlled so as to correct the TIS of the alignment detection system AS, accordingly.

Subsequently, the stage control system 19 begins a relative scanning in the Y-axis direction between the reticle R and the wafer W, that is, between the reticle stage RST and the wafer stage WST, in accordance with an instruction from the main controller 20. When both the stages (the RST and the WST) reach target scanning velocity severally and reach an at-constant-speed, synchronous state, a pattern area of the reticle R begins to be illuminated by the ultraviolet light from the illumination system 10 to begin the scanning exposure. The foregoing relative scanning is performed by the stage control system 19 that controls the reticle drive section (not shown) and the wafer stage drive section 24 while monitoring the measurement values of the wafer laser interferometer system 18 and the reticle interferometer 16.

The stage control system 19, particularly at the time of the foregoing scanning exposure, performs synchronous control to maintain a moving velocity Vr of the reticle stage RST in the Y-axis direction and a moving velocity Vw of the wafer stage WST at a velocity ratio in accordance with the projection magnification of the projection optical system PL (magnification of ¼ or ⅕).

Then, the scanning exposure of the first shot on the wafer W is complete when the different areas in the pattern area of the reticle R is sequentially illuminated by the ultraviolet pulse and illumination on the entire pattern area is finished. Thus, the pattern of the reticle R is reduced and transferred onto the first shot via the projection optical system PL.

When the scanning exposure of the first shot is finished as described above, the stage control system 19 moves the wafer stage WST in the X-axis and Y-axis directions in a stepping manner based on an instruction from the main controller 20 to move the wafer stage WST to the scanning starting position for exposure of the second shot.

The operation of each section is controlled by the stage control system 19 and a laser control unit (not shown) in the same manner as described above, and the same scanning exposure as above is performed to the second shot on the wafer W.

When pattern transfer to all shots subject to exposure on the wafer W is finished, the wafer W is replaced with the next wafer to perform the same alignment and exposure operation as the foregoing. However, the TIS measurement of the alignment detection system AS described above can be omitted for the second and later wafers in the same lot. This is because the same alignment marks are formed on the wafers in the same lot through the same processes and thus sufficiently highly accurate TIS correction is possible even if the TIS correction of the alignment measurement results uses the TIS values obtained from measurement of the first wafer.

Accordingly, regarding the second and later wafers in the lot, the positional measurement of the fiducial marks FM1 to FM4 may be omitted, performing only the positional measurement of the alignment marks provided in a plurality of particular shot areas (sample shots), which are previously selected, and thus the wafer alignment of the EGA method.

As is obvious from the foregoing description, in this embodiment, the wafer laser interferometer system 18, the main controller 20, the wafer holder 25, the vertical-movement-and-rotation mechanism 74 and the like constitute the measurement unit that measures the TIS of the alignment detection system AS. The main controller 20 constitutes the first detection control system, the second control system and the operation unit, and the main controller 20 and the stage controls system 19 constitute the control unit.

As has been described in detail, according to the exposure apparatus 100 of this embodiment, the positional information of the fiducial marks FM1 to FM4 formed on the wafer holder 25 and the positional information of the alignment marks AM1 to AM4 on the wafer W mounted on the wafer holder 25 are detected by using the alignment detection system AS and the wafer laser interferometer system 18 in the “first state” where the orientation of the wafer holder 25 is set to the predetermined direction on the wafer stage WST, and the positional information of each mark, the positional information of which has been detected in the “first state”, is detected again in the “second state” where the wafer holder 25 is rotated through 180° with respect to the “first state”. And then, a detection error, that is, the TIS caused by the alignment detection system AS is calculated by using respective detection results. In addition, since the TIS measurement can be performed by using an actual process wafer, there is no need to prepare a tool wafer, and the TIS is calculated based on the positional measurement results of the alignment marks on a wafer actually used in exposure. Therefore, the TIS of the alignment detection system AS for the actual process wafer can be measured in a short time and with high accuracy.

Further, the TIS of the alignment detection system AS obtained as described above is subtracted from the value that has been actually measured, and the alignment (a fine alignment) between the reticle R and each shot area on the wafer W is performed based on the subtracted value. Thus, highly accurate exposure can be realized due to the improvement of an overlay accuracy.

In this embodiment, the wafer holder 25 holding the wafer W has a constitution in which rotation through substantially 180° on the wafer stage WST is enabled. Therefore, TIS can be measured only by changing the state from the “first state” to the “second state” in each of which the orientation of the wafer holder 25 is set to a predetermined direction, even when the conventional TIS measurement using a tool wafer and the alignment detection system AS is performed. Accordingly, the step of, after a wafer is removed and rotated through 180°, mounting the wafer on the substrate holder again is not necessary, and the position shift of the wafer W before and after the rotation can be prevented. As a result, the stage unite of this embodiment can be preferably used for the TIS measurement of the alignment detection system AS.

In the foregoing embodiment, description has been made for the case where four fiducial plates (the fiducial mark) for measurement are provided on the wafer holder 25, all of which are subject to the positional measurement, where four alignment marks corresponding thereto are selected from alignment marks on the wafer W to perform the positional measurement thereof, and where using the mean value of the positions of the four fiducial marks and the mean value of the position of the alignment marks as the positional information the TIS of the alignment detection system AS is calculated based on the positional information. However, it is a matter of course that the present invention is not limited to this case.

The number of the fiducial marks and the alignment marks for obtaining the positional information to calculate the detection error caused by the mark detection system is not specifically limited. Any number of marks can be used as long as the positional relation between the fiducial marks and the alignment marks can be obtained. Accordingly, the number of the fiducial marks and the alignment marks may both be one, or either of the two may be one.

Furthermore, in this embodiment, description has been made for the case where the positions of a plurality of fiducial marks and alignment marks are measured, and for each of the fiducial and alignment marks, measurement results are averaged. The least-squares method may be used as the statistical computation.

Specifically, in the wafer alignment of the EGA method, a model expression given by the following expression (15) which represents a shot arrangement coordinate on the wafer W, and which includes six unknown parameters (error parameters) of (a, b, c, d, Ox, Oy) is postulated. In the expression (15), Fxn and Fyn are respectively the X coordinate and the Y coordinate, in the stage coordinate system, of a target position for positioning of a shot area on a wafer W. And Dxn and Dyn are the X coordinate and the Y coordinate of the shot area on design respectively,

$$[ \begin{matrix}F x n \\ Fy n\end{matrix} ] = [ \begin{matrix}a b \\ c d\end{matrix} ] [ \begin{matrix}D x n \\ Dy n\end{matrix} ] + [ \begin{matrix}O x \\ O y\end{matrix} ] \qquad ( 15 )$$

Then, the foregoing six parameters are determined such that an average deviation between the information of the arrangement coordinate (actual measurement value) obtained by the measurement of the alignment marks and a calculative arrangement coordinate determined in the model expression (15) becomes the minimum. The arrangement coordinate of each shot area is obtained by computation using the determined parameter and the model expression (15). Herein, the six parameters include offsets (Ox and Oy), in the X direction and the Y direction with respect to the stage coordinate system, of the shot arrangement. Herein, the main controller 20 performs the positional measurement of the alignment marks in the same manner as in the foregoing embodiment, and obtains the offsets (Ox and Oy) in the first and second states by using the measurement results.

Moreover, a model expression including offsets (HOx and HOy), in the X and Y directions with respect to the stage coordinate system, of the arrangement coordinates of the fiducial marks FM1 to FM4 on the wafer holder 25, which offsets are unknown parameters, is postulated similarly to the wafer alignment of the EGA method. Then, the offsets (HOx and HOy) in the X and Y directions are determined by using the least-square method such that the deviation between the positional information obtained from the positional measurement results regarding the fiducial marks FM1 to FM4 and the calculative values determined by the model expression becomes the minimum. The main controller 20 performs the positional measurement of the fiducial marks in the same manner as the foregoing embodiment, and calculates the offsets (HOx and HOy) in each of the first and second states by using the measurement result.

Then, the main controller 20 calculates differences between offsets Ox, Oy and Hox, HOy, which are represented by ΔOFF₁₈₀x, ΔOFF₀x, ΔOFF₁₈₀y and ΔOFF₀y, based on the following expressions (16) to (19) and stores the results in the memory,

ΔOFF₁₈₀x=O₁₈₀x−HO₁₈₀x (16)

ΔOFF₀x=HO₀x−O₀x (17)

ΔOFF₁₈₀y=O₁₈₀y−HO₁₈₀y (18)

ΔOFF₀y=HO₀y−O₀y. (19)

Herein, representing the real offset values regarding the X direction of the wafer and the wafer holder by Ox and HOx, the expressions (16) and (17) are expressed as follows,

$$\begin{matrix}Δ O F {F}_{180} x = ( O x + T I S x ) - H O x \\ = O x - H O x + T I S x\end{matrix} \qquad {( 16 )}^{′}$$

$$\begin{matrix}Δ O F {F}_{0} x = - H O x - ( - O x + T I S x ) \\ = O x - H O x - T I S x .\end{matrix} \qquad {( 17 )}^{′}$$

Similarly, representing the real offset values regarding the Y direction of the wafer and the wafer holder by Oy and Hoy, the expressions (18) and (19) are expressed as follows,

$$\begin{matrix}Δ O F {F}_{180} y = ( O y + T I S y ) - H O y \\ = O y - H O y + T I S y\end{matrix} \qquad {( 18 )}^{′}$$

$$\begin{matrix}Δ O F {F}_{0} y = - H o y - ( - O y + T I S y ) \\ = O y - H Oy - T I S y .\end{matrix} \qquad {( 19 )}^{′}$$

From the expressions (16)′ and (17)′, the X direction component of the TIS of the alignment detection system AS is as follows,

TISx=(ΔOFF₁₈₀x−ΔOFF₀x)/2. (20)

And, from the expressions (18)′ and (19)′, the Y direction component of the TIS of the alignment detection system AS is as follows,

TISy=(ΔOFF₁₈₀y−ΔOFF₀y)/2. (21)

Here, the main controller 20 calculates the TISx and the TISy based on the expressions (20) and (21), and the offsets of the wafer which are obtained in the second state and then corrected by using the calculated results are adopted as new Ox and Oy.

And then, the main controller 20, by using the model expression (15) where all the parameters including the new Ox and Oy have been determined, calculates the arrangement coordinates of the shot areas on the wafer W. According to the arrangement coordinates, the stage control system 19 performs exposure of the step-and-scan method like in the above-mentioned embodiment while controlling the position of the wafer stage WST (the wafer holder 25), in accordance with an instruction from the main controller 20. Upon the exposure, the position of the wafer stage WST (the wafer holder 25) is controlled so as to correct for the TIS of the alignment detection system AS.

Because by use of the unit of the first embodiment, a substrate such as a wafer or a tool wafer mounted on the wafer holder can be rotated through 180° together with the wafer holder, the center shift and rotation of the wafer does not cause the decrease of accuracy in measuring TIS. Considering that the accuracy of recent exposure apparatuses in aligning a substrate (wafer) is required to be of the order of 10 nm or less, there is a possibility that deformation of the wafer holder upon rotation may cause the decrease of accuracy in measuring TIS depending on the required level of the accuracy. Therefore, preferably, deformation of the wafer holder itself is also taken into account.

A second embodiment of this invention provided below allows for the foregoing point.

<<A Second Embodiment>>

In the following, the second embodiment of the present invention will be described on the basis of FIGS. 5A and 5B. An exposure apparatus according to the second embodiment is the same in construction as the exposure apparatus 100 of the first embodiment, but is different from the exposure apparatus 100 in that deformation upon rotation of the wafer holder itself is measured for TIS measurement of the alignment detection system. The description will be centered on the difference for avoiding the same explanations, and the same symbols are used to indicate components that are the same as or equivalent to those in the first embodiment, the explanations of which components are omitted.

Next, an operation sequence of the exposure apparatus 100 of the second embodiment including an operation for measuring deformation of the wafer holder 25 and an operation for performing exposure for a second or later layer on a lot of (e.g. 25) wafers W will be described.

First, in the same way as in the above, a sequence of preparation including loading of a reticle R onto the reticle stage RST, reticle alignment, and base-line measurement is performed.

After the completion of the above preparation sequence, the operation described below for measuring deformation of the wafer holder is started.

First, in the operation for measuring deformation of the wafer holder a wafer loader (not shown) loads a measurement wafer WT, not coated with a resist as a photosensitive material, as a substrate exclusively for measurement onto the wafer holder 25, and then the wafer WT is fixed with vacuum chuck.

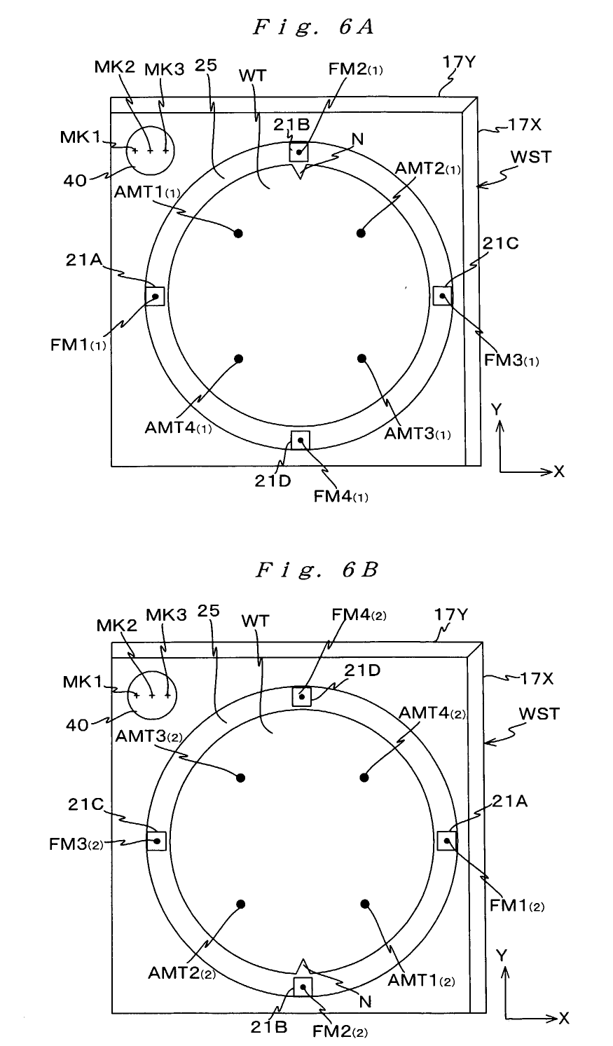

Provided on the measurement wafer WT are a plurality of holder-deformation-measurement marks (hereinafter, called “measurement marks”) AMTn as first marks (measurement marks), which are represented by four measurement marks AMT1 to AMT4 in FIG. 6A. The measurement marks are identical in shape to the fiducial marks FMn as second marks provided on the wafer holder 25, and each are, for example, a mark which comprises a X-axis mark that consist of, for example, 6 μm L/S marks arranged in the X-axis direction and a Y-axis mark that consist of, for example, 6 μm L/S marks arranged in the Y-axis direction, and whose lines and spaces are thick enough not to be affected by TIS of the alignment detection system AS.

A pre-alignment unit (not shown) positions the measurement wafer WT such that its center and orientation are close to a target position and direction respectively. Upon loading of the wafer the yawing of the wafer stage WST is controlled by means of the wafer laser interferometer system 18. Therefore, the measurement wafer WT is loaded onto the wafer holder 25 such that the direction in which the V-shaped notch N faces substantially coincides with the +Y direction of the stage coordinate system as shown in FIG. 6A, which direction is called “180° direction” herein after. The positional relation between the measurement wafer WT and the wafer holder 25 is called “first state” hereinafter.

In this first state, measurement of the wafer holder 25 and the measurement wafer WT held on the wafer holder 25 is performed in the following manner.

First, the main controller 20 measures position-coordinates AMTn₍₁₎ (AMT1₍₁₎, AMT2₍₁₎, AMT3₍₁₎, AMT4₍₁₎) of the measurement marks AMTn (n=1,2,3,4) provided on the measurement wafer WT, and the position-coordinates FMn₍₁₎ (FM1₍₁₎, FM2₍₁₎, FM3₍₁₎, FM4₍₁₎) of the fiducial marks FMn provided on the wafer holder 25.

Specifically, the stage control system 19, according to instructions from the main controller 20, positions the fiducial marks and the measurement marks sequentially underneath the alignment detection system AS by controlling the XY-two-dimensional movement of the wafer stage WST while monitoring the measurement value of the wafer laser interferometer system 18, and each time, the main controller 20 stores the corresponding measurement value of the alignment detection system AS, i.e. information on the mark's position with respect to the index center of the alignment detection system AS, and the corresponding measurement value of the wafer laser interferometer system 18 in a memory 80. The main controller 20, as disclosed in Japanese Patent Laid-Open 2000-77295 for example, detects the focus position by measuring asymmetry, or the difference in image intensity between raised and lower portions, of the image corresponding to the edges of the fiducial mark and the alignment mark, which consist of a phase pattern, while moving the wafer holder 25 in the Z-axis direction by given steps via the Z-tilt stage 30, and detects each mark at that Z-position (the best focus state).

Here, the measurement order is the same as in the case of the marks AMn, FMn. That is, like in FIG. 5A, the fiducial marks FMn may be sequentially measured along a circumference after measuring the measurement marks AMTn on the measurement wafer WT sequentially along a circumference. Alternatively, to shorten the measurement time and the drive distance of the wafer stage WST, the measurement marks AMTn and the fiducial marks FMn may be alternately measured along the circumference, like in FIG. 5B.

Next, based on the measuring results and the base-line amount measured beforehand the main controller 20 calculates the position coordinates AMTn₍₁₎ (AMT1₍₁₎, AMT2₍₁₎, AMT3₍₁₎, AMT4₍₁₎) in the stage coordinate system of the measurement marks AMTn (n=1,2,3,4) formed on the measurement wafer WT and the position coordinates FMn₍₁₎ (FM1₍₁₎, FM2₍₁₎, FM3₍₁₎, FM4₍₁₎) in the stage coordinate system of the fiducial marks FMn provided on the wafer holder 25.

Next, the main controller 20 performs the operation of the following expression (22) to obtain the center position H₍₁₎ of the wafer holder 25 in the first state where the orientation of the wafer W is set to the 180° direction,

H₍₁₎=(FM1₍₁₎+FM2₍₁₎+FM3₍₁₎+FM4₍₁₎)/4. 22)

It is a matter of course that H₍₁₎ is actually a two-dimensional coordinate value.

Then, the main controller 20 calculates position coordinate WT₍₁₎ of a representative point on the measurement wafer WT in the first state based on the following expression (23),

WT₍₁₎=(AMT1₍₁₎+AMT2₍₁₎+AMT3₍₁₎+AMT4₍₁₎)/4. 23)

It is a matter of course that WT₍₁₎ is actually a two-dimensional coordinate value.

Subsequently, the main controller 20 calculates a distance Lx₍₁₎ in the X-axis direction and a distance Ly₍₁₎ in the Y-axis direction between the wafer holder 25's center position and the representative point on the measurement wafer WT in the first state, based on the following expressions (24) and (25) respectively, and stores the calculation results in the memory 80,

Lx₍₁₎=WTx₍₁₎−Hx₍₁₎ (24)

Ly₍₁₎=WTy₍₁₎−Hy₍₁₎. (25)

Here, the distance Lx₍₁₎ in the X-axis direction and the distance Ly₍₁₎ in the Y-axis direction can be also expressed in the following expressions (24)′ and (25)′ respectively,

$$\begin{matrix}{Lx}_{( 1 )} = ( WTx + {Hx}_{( 1 )} ) - {Hx}_{( 1 )} \\ = WTx ,\end{matrix} \qquad {( 24 )}^{′}$$

where WTx is the X coordinate value (a real value) of the representative point on the measurement wafer WT in a holder coordinate system having its origin at the center of the wafer holder and the coordinate axes parallel to those of the stage coordinate system (X, Y),

$$\begin{matrix}{Ly}_{( 1 )} = ( WTy + {Hy}_{( 1 )} ) - H {y}_{( 1 )} \\ = WTy ,\end{matrix} \qquad {( 25 )}^{′}$$

where WTy is the Y coordinate value (a real value) of the representative point on the measurement wafer WT in the foregoing holder coordinate system.

When the measurement in the first state is finished as described above, the stage control system 19 controls the vertical-movement-and-rotation mechanism 74 in accordance with instructions from the main controller 20 to elevate the wafer holder 25 to the level shown in FIG. 2 in the state where the measurement wafer WT is held by vacuum chuck, to rotate it through 180°, and then to lower it to the original height. Note that FIG. 6B shows a state of the wafer WT and the wafer holder 25 after the rotation through 180°, which state is referred to as a “second state” hereinafter.

In the second state, the wafer WT is directed in the 0° direction, which is such a direction that the notch, as seen from the wafer center, faces in the −Y direction. In the same manner as for the foregoing case of the first state, the position coordinates AMTn₍₂₎ (AMT1₍₂₎, AMT2₍₂₎, AMT3₍₂₎, AMT4₍₂₎) of the measurement marks AMTn (n=1,2,3,4) and the position coordinates FMn₍₂₎ (FM1₍₂₎, FM2₍₂₎, FM3₍₂₎, FM4₍₂₎) of the fiducial marks FMn provided on the wafer holder 25 are measured under the control of the main controller 20.

In this case, the actually measured values of the measurement mark AMTn and the fiducial mark FMn include deformation ΔJ of the wafer holder 25 due to heat generated upon its rotation, ΔJ being a change from the first state.

Next, the main controller 20 performs operation of the following expression (26) to obtain the center position H₍₂₎ of the wafer holder 25 in the second state where the orientation of the measurement wafer WT is set to the 0° direction,

H₍₂₎=(FM1₍₂₎+FM2₍₂₎+FM3₍₂₎+FM4₍₂₎)/4. (26)

It is a matter of course that H₍₂₎ is actually a two-dimensional coordinate value.

Next, the main controller 20 calculates the position coordinate WT₍₂₎ of the representative point on the measurement wafer WT in the second state based on the following expression (27),

WT₍₂₎=(AM1₍₂₎+AM2₍₂₎+AM3₍₂₎+AM4₍₂₎)/4. (27)

It is a matter of course that WT₍₂₎ is actually a two-dimensional coordinate value.

Subsequently, the main controller 20 calculates a distance Lx₍₂₎ in the X-axis direction and a distance Ly₍₂₎ in the Y-axis direction between the wafer holder center position and the representative point on the measurement wafer WT in the second state, based on the following expressions (28) and (29) respectively, and stores the calculation results in the memory 80,

Lx₍₂₎=Hx₍₂₎−WTx₍₂₎ (28)

Ly₍₂₎=Hy₍₂₎−WTy₍₂₎. (29)

Here, when moving from the “first state” to the “second state”, the wafer holder 25 holding the measurement wafer WT is rotated through 180° around the center of the rotation axis (the center of the holder coordinate system) of the wafer holder 25 while maintaining the positional relation between the wafer holder 25 and the measurement wafer WT and the position of the alignment detection system AS. Accordingly, the distance Lx₍₂₎ in the X-axis direction and the distance Ly₍₂₎ in the Y-axis direction between the wafer holder center position and the representative point on the measurement wafer WT can be expressed by the following expressions (28)′ and (29)′ respectively, using the real values WTx, WTy in the first state,

$$\begin{matrix}{Lx}_{( 2 )} = {Hx}_{( 2 )} - ( {Hx}_{( 2 )} - WTx + Δ Jx ) \\ = W T x - Δ J x\end{matrix} \qquad {( 28 )}^{′}$$

$$\begin{matrix}L {y}_{( 2 )} = H {y}_{( 2 )} - ( H {y}_{( 2 )} - W T y + Δ J y ) \\ = W T y - Δ J y .\end{matrix} \qquad {( 29 )}^{′}$$

Here, ΔJx, ΔJy are X- and Y-components of deformation of the wafer holder 25. The following expressions for ΔJx, ΔJy are obtained from the foregoing expressions (24)′, (28)′, and (25)′, (29)′,

ΔJx=Lx₍₁₎−Lx₍₂₎ (30)

ΔJy=Ly₍₁₎−Ly₍₂₎. (31)

And then, the main controller 20 calculates the X- and Y-components of deformation of the wafer holder 25 between the first and second states based on the above expressions (30) and (31), and stores them in the memory 80.

Next, wafer processing operation is started where a wafer unloader (not shown) unloads the measurement wafer WT from the wafer holder 25, and a loader (not shown) loads a first wafer W of a lot onto the wafer holder 25 to be fixed by vacuum chuck. In this loading, the wafer W is loaded onto the wafer holder 25 such that the direction in which the notch N faces as seen from the wafer center substantially coincides with the +Y direction (180° direction) like in FIG. 4A. This state of the wafer stage WST (positional relation between the wafer W and the wafer holder 25) is called “third state” hereinafter.

In the third state, the main controller 20 measures position-coordinates AMn₍₃₎ (AM1₍₃₎, AM2₍₃₎, AM3₍₃₎, AM4₍₃₎) of the alignment marks AMn (n=1,2,3,4) provided on the wafer W, and the position-coordinates FMn₍₃₎ (FM1₍₃₎, FM2₍₃₎, FM3₍₃₎, FM4₍₃₎) of the fiducial marks FMn provided on the wafer holder 25 like in the first and second states.

Also in this case, the measurement order is the same as in the first state. As shown in FIG. 5A, the fiducial marks FMn may be sequentially measured along a circumference after measuring the alignment marks AMn on the wafer W sequentially along a circumference. Alternatively, to shorten the measurement time and the drive distance of the wafer stage WST, the alignment marks AMn and the fiducial marks FMn may be alternately measured along the circumference, as shown in FIG. 5B.

Next, the main controller 20 calculates the position coordinates AMn₍₃₎ (AM1₍₃₎, AM2₍₃₎, AM3₍₃₎, AM4₍₃₎) in the stage coordinate system of the alignment marks AMn (n=1,2,3,4) formed on the wafer W and the position coordinates FMn₍₃₎ (FM1₍₃₎, FM2₍₃₎, FM3₍₃₎, FM4₍₃₎) in the stage coordinate system of the fiducial marks FMn provided on the wafer holder 25.

Next, based on the measuring results and the base-line amount measured beforehand the main controller 20 performs the operation of the following expression (32) to obtain the center position H₍₃₎ of the wafer holder 25 in the third state where the orientation of the wafer W is set to the 180° direction,

H₍₃₎=(FM1₍₃₎+FM2₍₃₎+FM3₍₃₎+FM4₍₃₎)/4. (32)

It is a matter of course that the H₍₃₎ is actually a two-dimensional coordinate value.

Then, the main controller 20 calculates position coordinate W₍₃₎ of a representative point on the wafer W in the third state based on the following expression (33),

W₍₃₎=(AM1₍₃₎+AM2₍₃₎+AM3₍₃₎+AM4₍₃₎)/4. (33)

It is a matter of course that the W₍₃₎ is actually a two-dimensional coordinate value.

Subsequently, the main controller 20 calculates a distance Lx₍₃₎ in the X-axis direction and a distance Ly₍₃₎ in the Y-axis direction between the holder center position and the representative point on the wafer W in the third state, based on the following expressions (34) and (35) respectively, and stores the calculation results in the memory 80,

Lx₍₃₎=Wx₍₃₎−Hx₍₃₎ (34)

Ly₍₃₎=Wy₍₃₎−Hy_{(3).} (35)

Here, the distance Lx₍₃₎ in the X-axis direction and the distance Ly₍₃₎ in the Y-axis direction can be also expressed in the following expressions (34)′ and (35)′ respectively,

$$\begin{matrix}{Lx}_{( 3 )} = ( Wx + {Hx}_{( 3 )} + TISx ) - {Hx}_{( 3 )} \\ = Wx + TISx ,\end{matrix} \qquad {( 34 )}^{′}$$

where Wx is the X coordinate value (a real value) of the representative point on the wafer W in the holder coordinate system, and TISx is the X-component of TIS of the alignment detection system AS,

$$\begin{matrix}L {y}_{( 3 )} = ( W y + H {y}_{( 3 )} + TIS y ) - H {y}_{( 3 )} \\ = W y + TIS y ,\end{matrix} \qquad {( 35 )}^{′}$$

where Wy is the Y coordinate value (a real value) of the representative point on the wafer W in the holder coordinate system, and TISy is the Y-component of TIS of the alignment detection system AS.

When the measurement in the third state is finished as described above, the stage control system 19 controls the vertical-movement-and-rotation mechanism 74 in accordance with instructions from the main controller 20 to elevate the wafer holder 25 to the level shown in FIG. 2 in the state where the wafer W is held by vacuum chucking, and after that, the wafer holder 25 is rotated through 180° and then lowered to the original height by the stage control system 19 via the vertical-movement-and-rotation mechanism 74. Note that FIG. 4B shows a state of the wafer W and the wafer holder 25 after the rotation through 180°, which state is referred to as a “fourth state” hereinafter.

In the fourth state, the wafer WT is directed in the 0° direction, which is such a direction that the notch, as seen from the wafer center, faces in the −Y direction. In the same manner as for the foregoing case of the third state, the position coordinates AMn₍₄₎ (AM1₍₄₎, AM2₍₄₎, AM3₍₄₎, AM4₍₄₎) of the alignment marks AMn (n=1,2,3,4) and the position coordinates FMn₍₄₎ (FM1₍₄₎, FM2₍₄₎, FM3₍₄₎, FM4₍₄₎) of the fiducial marks FMn provided on the wafer holder 25 are measured under the control of the main controller 20.

In this case, the actually measured value of the fiducial mark FMn includes deformation ΔJ of the wafer holder 25 due to heat generated upon its rotation, ΔJ being a change from the third state and assumed to be the same as from the first state to the second state.

Next, the main controller 20 performs operation of the following expression (36) to obtain the center position H₍₄₎ of the wafer holder 25 in the fourth state where the orientation of the wafer W is set to the 0° direction,

H₍₄₎=(FM1₍₄₎+FM2₍₄₎+FM3₍₄₎+FM4₍₄₎)/4. (36)

It is a matter of course that H₍₄₎ is actually a two-dimensional coordinate value.

Next, the main controller 20 calculates the position coordinate WT₍₄₎ of the representative point on the wafer W in the fourth state based on the following expression (37),

WT₍₄₎=(AM1₍₄₎+AM2₍₄₎+AM3₍₄₎+AM4₍₄₎)/4 (37)

It is a matter of course that WT₍₄₎ is actually a two-dimensional coordinate value.

Subsequently, the main controller 20 calculates a distance Lx₍₄₎ in the X-axis direction and a distance Ly₍₄₎ in the Y-axis direction between the wafer holder center position and the representative point on the wafer W in the fourth state, based on the following expressions (38) and (39) respectively, and stores the calculation results in the memory 80,

Lx₍₄₎=Hx₍₄₎−Wx₍₄₎ (38)

Ly₍₄₎=Hy₍₄₎−Wy₍₄₎. (39)

Here, when moving from the “third state” to the “fourth state”, the wafer holder 25 holding the wafer W is rotated through 180° around the center of the rotation axis of the wafer holder 25 while maintaining the positional relation between the wafer holder 25 and the wafer W and the position of the alignment detection system AS. Accordingly, the distance Lx₍₄₎ in the X-axis direction and the distance Ly₍₄₎ in the Y-axis direction between the wafer holder center position and the representative point on the wafer W can be expressed by the following expressions (38)′ and (39)′ respectively,

$$\begin{matrix}L {x}_{( 4 )} = H {x}_{( 4 )} - ( H {x}_{( 4 )} - W x + T I S x + Δ J x ) \\ = W x - T I S x - Δ J x\end{matrix} \qquad {( 38 )}^{′}$$

$$\begin{matrix}L {y}_{( 4 )} = H {y}_{( 4 )} - ( H {y}_{( 4 )} - W y + T I S y + Δ J y ) \\ = W y - T I S y - Δ J y .\end{matrix} \qquad {( 39 )}^{′}$$

The following expressions are obtained from the foregoing expressions (34)′, (38)′, and (35)′, (39)′,

Lx₍₃₎−Lx₍₄₎=2TISx+ΔJx (40)

Ly₍₃₎−Ly₍₄₎=2TISy+ΔJy (41)

That is,

TISx=(Lx₍₃₎−Lx₍₄₎)/2−ΔJx/2 (40)′

TISy=(Ly₍₃₎−Ly₍₄₎)/2−ΔJy/2 (41)′

By substituting the expressions (30), (31) into the expressions (40)′, (41)′ respectively, the following expressions for TISx, TISy are obtained,

TISx=(Lx₍₃₎−Lx₍₄₎)/2−(Lx₍₁₎−LX₍₂₎)/2 (40)″

TISy=(Ly₍₃₎−Ly₍₄₎)/2−(Ly₍₁₎−Ly₍₂₎)/2 (41)″

And then, the main controller 20 calculates TISx, TISy of the alignment detection system AS based on the expressions (40)″ and (41)″, and stores them in the memory 80.

The TIS of the alignment detection system AS obtained as above is subtracted from the position coordinates AMn₍₄₎ (AM1₍₄₎, AM2₍₄₎, AM3₍₄₎, AM4₍₄₎) of the alignment marks, which have been measured in the fourth state, to obtain real positions AMn₍₀₎ of the alignment marks.

That is, the main controller 20 performs a TIS correction on the results of measuring the alignment mark positions based on the following expression (42),

AMn₍₀₎=AMn₍₄₎−TIS. (42)

After fine alignment using the enhanced global alignment (EGA) method, which calculates arrangement coordinates of shot areas on the wafer W, based on the corrected values like in the first embodiment, the pattern on a reticle R is transferred onto all shot areas subject to exposure on the wafer W, following the step-and-scan method.

When transfer of the pattern to all shot areas on the wafer W is finished, the wafer W is replaced with the next wafer to perform the same alignment and exposure operation as the foregoing. However, the TIS measurement of the alignment detection system AS described above can be omitted for the second and later wafers in the same lot. This is because the same alignment marks are formed on the wafers in the same lot through the same processes and thus sufficiently highly accurate TIS correction of the alignment measurement results is possible even if using the TIS values obtained from measurement of the first wafer.

When, after the completion of the lot, performing a wafer of a next lot, only measurement in the third and fourth states may be performed omitting measurement in the first and second states for measuring deformation of the wafer holder.

As seen in the above description, in the second embodiment, the first, second, third, and fourth detection control systems, the controller, and the first and second computing units are implemented by the main controller 20. That is, while in this embodiment the first, second, third, and fourth detection control systems, the controller, and the first and second computing units are implemented as software programs installed in the main controller 20, not being limited to this, at least some of the first, second, third, and fourth detection control systems, the controller, and the first and second computing units may be implemented by hard wares, needless to say.

As described in detail above, according to the exposure apparatus of the second embodiment the main controller 20 detects position information of a plurality of measurement marks (e.g. the measurement marks AMTn and the fiducial marks FMn) provided on the face of the wafer holder 25 mounted on the wafer stage WST, on which face a wafer is mounted, by means of the wafer laser interferometer system 18 for detecting position of the wafer stage WST and the alignment detection system AS for detecting marks on the wafer stage WST, in the first state where the orientation of the wafer holder 25 is set to the 180° direction. And in the second state where the orientation of the wafer holder 25 is set to the 0° direction by rotating it through 180° from the first state by the wafer stage drive section 24, the main controller 20 detects position information of the plurality of measurement marks (e.g. the measurement marks AMTn and the fiducial marks FMn) provided on the wafer holder 25, by means of the wafer laser interferometer system 18 and the alignment detection system AS. And the main controller 20 calculates deformation of the wafer holder 25 due to the change from the first state to the second state based on the results of measuring position information in the first and second states.

That is, if there is no deformation cause, positional relations between the plurality of measurement marks on the wafer holder 25 should not change between the first state and the second state, where the wafer holder has been rotated through 180° from the first state. Therefore, when deformation of the wafer holder 25 occurs due to the rotation thereof, positional relations between the plurality of measurement marks change according to the deformation. Therefore, by performing a predetermined computation based on position information of the plurality of measurement marks in the first state as a reference and position information of the plurality of measurement marks affected by deformation of the wafer holder 25 in the second state, the deformation of the wafer holder 25 can be calculated easily and accurately.

As described above, using only the results of measuring position information of the plurality of measurement marks in the first state and the second state, where the wafer holder has been rotated through 180° from the first state, the deformation of the wafer holder 25 can be calculated easily and accurately. Here, also because marks that hardly cause a detection error such as TIS of the alignment detection system AS are employed as measurement marks of which such position information is to be detected, the deformation of the wafer holder 25 can be calculated easily and accurately.

Further, in this embodiment the main controller 20 detects position information of alignment marks AMn provided on a wafer W and the fiducial marks FMn in the third state where the orientation of the wafer holder 25 is set to the same as in the first state, and detects position information of the marks whose position information has been measured in the third state, in the fourth state where the wafer holder 25 has been rotated through 180° from the third state. And the main controller 20 calculates the real detection shift (TIS) due to the alignment detection system AS based on a seeming detection shift (including TIS and the detection error due to the wafer holder's deformation) of the alignment detection system AS calculated using the detecting results and based on the deformation amount of the wafer holder 25 stored in the memory 80. That is, the real detection shift (TIS) due to the alignment detection system AS can be calculated easily and accurately by performing a predetermined computation based on position information of the alignment marks AMn and the fiducial marks FMn in the third and fourth states and the deformation amount of the wafer holder obtained beforehand.

That is, if there is no deformation cause, positional relations between the alignment marks AMn and the fiducial marks FMn should not change between the third state and the fourth state, where the wafer holder has been rotated through 180° from the third state. Therefore, the typical causes that positional relations between the alignment marks AMn and the fiducial marks FMn change between the third state and the fourth state are deformation of the wafer holder 25 and TIS of the alignment detection system AS upon measuring the alignment marks. Therefore, by subtracting deformation amount of the wafer holder due to the change from the third (or first) state to the fourth (or second) state stored in the memory 80 from a change between the third and fourth states (a seeming detection shift due to the alignment detection system AS), TIS of the alignment detection system AS can be calculated easily and accurately.

In this case, because the real detection shift due to the alignment detection system AS such as TIS is calculated based on the results of measuring positions of alignment marks on a wafer actually exposed in the real manufacturing process, TIS of the alignment detection system AS can be measured for actual wafers in the process for a short time and accurately.

In the second embodiment, because the main controller 20, upon exposure, controls position of the wafer stage WST so as to correct for TIS of the alignment detection system AS calculated accurately, a reticle pattern can be accurately transferred onto a wafer W, that is, circuit patterns can be accurately formed on a wafer.

The second embodiment describes the case where the four fiducial marks provided on the wafer holder are all subject to position measurement, where four measurement marks corresponding to them are selected from measurement marks on a measurement wafer to measure positions thereof, where based on the mean of positions of the four fiducial marks and the mean of positions of the four measurement marks as position information, the deformation amount of the wafer holder is calculated, and where based on likewise-calculated position information of alignment marks on a wafer W, TIS of the alignment detection system is measured. However, this invention is not limited to that, needless to say.

That is, the number of fiducial marks, measurement marks, and alignment marks whose position information is obtained to calculate the detection error due to the mark detection system does not matter, and positional relations between fiducial marks and alignment marks need only be obtained. Therefore, both or either of the number of fiducial marks and the number of alignment marks may be one, that is, at least one measurement for each type of mark need be performed.

Further, while the second embodiment describes the case where the deformation of the wafer holder is calculated using the mean of measured positions of a plurality of fiducial marks and the mean of measured positions of a plurality of measurement marks, the least-squares method may be used as the statistical process in the calculation.

Next, the method for obtaining the deformation of the wafer holder and TIS of the alignment detection system by use of the EGA method will be described as an example.

As a premise, it is assumed that a model expression (and six unknown parameters such as X- and Y-directions offsets TOx, TOy) for arrangement coordinates of measurement marks including AMT1 to AMT4 on a measurement wafer WT, and a model expression (and six unknown parameters such as X- and Y-directions offsets HOx, Hoy) for arrangement coordinates of fiducial marks FM1 to FM4 on the wafer holder 25 are the same as the expression provided in the above-described wafer alignment following the EGA method.

First, the main controller 20, in the first state (see FIG. 6A), measures positions of the measurement marks AMT1 to AMT4 on the measurement wafer WT and the fiducial marks FM1 to FM4 on the wafer holder 25 like in the above embodiment.

Next, the main controller 20, by use of the least-squares method, determines values of at least X- and Y-directions offsets TOx₍₁₎, TOy₍₁₎ of the six unknown parameters for which the sum of the squares of the deviations between measured positions of the measurement marks AMT1 to AMT4 and calculated values by use of the model expression for arrangement coordinates of measurement marks is minimal, and stores them in the memory 80.

And the main controller 20, by use of the least-squares method, determines values of at least X- and Y-directions offsets HOx₍₁₎, HOy₍₁₎ of the six unknown parameters for which the sum of the squares of the deviations between measured positions of the fiducial marks FM1 to FM4 and calculated values by use of the model expression for arrangement coordinates of the fiducial marks FM1 to FM4 is minimal, and stores them in the memory 80.

Next, the main controller 20 calculates, likewise, offsets TOx₍₂₎, TOy₍₂₎ and offsets HOx₍₂₎, HOy₍₂₎ for the second state (see FIG. 6B), where the measurement wafer WT and the wafer holder 25 have been rotated through 180° from the first state, and stores them in the memory 80.

Then, the main controller 20 calculates the differences ΔOFFx₍₁₎, ΔOFFx₍₂₎, ΔOFFy₍₁₎, ΔOFFy₍₂₎ between the offsets stored in the memory 80 given by the expressions (43) to (46), and stores them in the memory 80,

ΔOFFx₍₁₎=TOx₍₁₎−HOx₍ₗ₎ (43)

ΔOFFy₍₁₎=TOy₍₁₎−HOy₍₁₎ (44)

ΔOFFx₍₂₎=HOx₍₂₎^{-TOx}₍₂₎ (45)

ΔOFFy₍₂₎=HOy₍₂₎−TOy₍₂₎. (46)

Let TOx, TOy be real offsets in the X- and Y-directions of the measurement wafer WT respectively. The expressions (43), (44) are rewritten as the expressions (43)′, (44)′,

$$\begin{matrix}Δ O F F {x}_{( 1 )} = ( TOx + {HOx}_{( 1 )} ) - {HOx}_{( 1 )} \\ = TOx\end{matrix} \qquad {( 43 )}^{′}$$

$$\begin{matrix}Δ O F F {y}_{( 1 )} = ( T O y + H O {y}_{( 1 )} ) - H O {y}_{( 1 )} \\ = T O y .\end{matrix} \qquad {( 44 )}^{′}$$

Let Δjx, Δjy be errors of the X-direction offset and the Y-direction offset due to the holder's deformation respectively, then the expressions (45), (46) are rewritten as the expressions (45)′, (46)′,

$$\begin{matrix}Δ O F F {x}_{( 2 )} = H O {x}_{( 2 )} - ( H O {x}_{( 2 )} - T O x + Δ j x ) \\ = T O x - Δ j x\end{matrix} \qquad {( 45 )}^{′}$$

$$\begin{matrix}Δ O F F {y}_{( 2 )} = H O {y}_{( 2 )} - ( H O {y}_{( 2 )} - T O y + Δ j y ) \\ = T O y - Δ j y .\end{matrix} \qquad {( 46 )}^{′}$$

The expressions (47), (48) for errors of the X-direction offset Δjx and the Y-direction offset Δjy due to the holder's deformation respectively are obtained from the expressions (43)′, (45)′ and (44)′, (46)′,

Δjx=ΔOFFx₍₁₎−ΔOFFx₍₂₎ (47)

Δjy=ΔOFFy₍₁₎−ΔOFFy₍₂₎. (48)

The main controller 20 calculates Δjx, Δjy based on the expressions (47), (48) and stores them in the memory 80.

Next, the measurement wafer WT is unloaded from the wafer holder 25, and a wafer to be exposed is loaded onto the wafer holder 25. And the main controller 20 measures the alignment marks AM1 to AM4 on the wafer W and the fiducial marks FM1 to FM4 on the wafer holder 25 in the third and fourth states (see FIGS. 4A, 4B) like in the above embodiment, and calculates the offsets of the wafer W and the wafer holder 25 in each state.

Let OX₍₃₎, Hx₍₃₎, OX₍₄₎, Hx₍₄₎ be the offsets of the wafer W and the wafer holder 25 in the third state and the offsets of the wafer W and the wafer holder 25 in the fourth state respectively. The main controller 20 calculates the difference between the offsets ΔOFFx₍₃₎, ΔOFFy₍₃₎, ΔOFFx₍₄₎, ΔOFFy₍₄₎ based on the expressions (49) to (52), and stores them in the memory 80,

ΔOFFx₍₃₎=Ox₍₃₎−HOx₍₃₎ (49)

ΔOFFy₍₃₎=Oy₍₃₎−HOy₍₃₎ (50)

ΔOFFx₍₄₎=HOx₍₄₎−Ox₍₄₎ (51)

ΔOFFy₍₄₎=HOy₍₄₎−Oy₍₄₎. (52)

Let Ox, Oy be real offsets in the X- and Y-directions of the wafer W. The expressions (49) to (52) are rewritten as the expressions (49)′ to (52)′ respectively,

$$\begin{matrix}Δ O F F {x}_{( 3 )} = ( O x + H O {x}_{( 3 )} + T I S x ) - H O {x}_{( 3 )} \\ = O x + T I S x\end{matrix} \qquad {( 49 )}^{′}$$

$$\begin{matrix}Δ O F F {y}_{( 3 )} = ( O y + H O {y}_{( 3 )} + T I S y ) - H O {y}_{( 3 )} \\ = O y + T I S y\end{matrix} \qquad {( 50 )}^{′}$$

$$\begin{matrix}Δ O F F {x}_{( 4 )} = H O {x}_{( 4 )} - ( H O {x}_{( 4 )} - O x + T I S x + Δ j x ) \\ = O x - T I S x - Δ j x\end{matrix} \qquad {( 51 )}^{′}$$

$$\begin{matrix}Δ O F F {y}_{( 4 )} = H O {y}_{( 4 )} - ( H O {y}_{( 4 )} - O y + T I S y + Δ j y ) \\ = O y - T I S y - Δ j y .\end{matrix} \qquad {( 52 )}^{′}$$

The X-direction component of TIS of the alignment detection system AS is expressed by the expression (53) obtained from the expressions (49)′, (51)′,

TISx=(ΔOFFx₍₃₎−ΔOFFx₍₄₎)/2−Δjx/2. (53)

The Y-direction component of TIS of the alignment detection system AS is expressed by the expression (54) obtained from the expressions (50)′, (52)′,

TISy=(ΔOFFy₍₃₎−ΔOFFy₍₄₎)/2−Δjy/2 (54)

Then the main controller 20 calculates TISx, TISy by use of the expressions (53), (54) based on the values of Δjx, Δjy stored in the memory 80, and by use of the calculating results, corrects the offsets of the wafer obtained in the fourth state to obtain new offsets Ox, Oy.

And the main controller 20, by using the model expression (15) where all the parameters including the new Ox and Oy have been determined, calculates the arrangement coordinates of shot areas on the wafer W. According to the arrangement coordinates, the stage control system 19 performs exposure of the step-and-scan method like in the above-mentioned embodiment while controlling the position of the wafer stage WST (the wafer holder 25), in accordance with instructions from the main controller 20. Upon the exposure, the position of the wafer stage WST (the wafer holder 25) is controlled so as to correct for the TIS of the alignment detection system AS.

While the above description takes only X-direction and Y-direction offsets out of the six unknown parameters for denoting the deformation of the wafer holder, the other parameters can also be taken to calculate the deformation amount of the wafer holder and thus the measurement error (TIS) of the alignment detection system AS.

While in the above description positions of at least three marks of each of the group of measurement marks and the group of fiducial marks are measured when calculating the deformation amount of the wafer holder by use of the least-squares method, not being limited to this, for example, at least three marks of the whole group of measurement marks and fiducial marks may be measured in the first and second states to obtain the deformation amount of the wafer holder by comparing two groups of values of the parameters for the two states calculated based on the measuring results. Alternatively, at least three marks on the measurement wafer may only be measured in the first and second states to obtain the deformation amount of the wafer holder by comparing two groups of values of the parameters for the two states calculated based on the measuring results.

It is remarked that in the case of calculating the deformation amount of the wafer holder and TIS of the alignment detection system AS by use of the least-squares method like in the above, marks to be measured may be different between before (the first and third states) and after (the second and fourth states) the rotation of the wafer holder while marks to be measured are preferably the same in terms of measurement accuracy.

In the method of selecting marks subject to position detection for calculating the deformation amount of the wafer holder, only marks provided outside the area of the wafer holder on which a wafer is mounted may be selected.

Further, by providing fiducial marks FM₍ᵢₙ₎ within the area of the wafer holder on which a wafer is mounted and using them instead of the measurement marks AMTn on the measurement wafer WT to calculate the deformation amount of the wafer holder, the deformation amount can be easily measured even without the tool wafer WT, in which case the measurement is performed with vacuum of the wafer holder being off.

Note that in the above embodiments the alignment method of the wafer W is not limited to the EGA method, but that a die-by-die method may be adopted. In this case as well, each shot coordinate to be measured may be corrected by using the TIS of the alignment detection system AS previously obtained as described above.

In the foregoing embodiment, the wafer holder 25 is described to be rotated through 180°. The rotation of the wafer holder is preferably 180°±0 as an ideal value. However, due to an accuracy restriction by means for realizing the rotation mechanism and an accuracy required in the TIS measurement, an actual rotation angle may include an allowance to 180° (for example, 180° ±about 10 minutes or a few mrad). This is why the expression “substantially 180°” is used. Specifically, the “substantially 180°” described in this specification is the rotation angle including the allowance to 180°.

The arrangement method of the fiducial marks on the wafer holder 25 is not limited to the method where the fiducial plates for measurement having the fiducial marks formed thereon is fixed on the wafer holder 25 and which is shown in each embodiment, but a method where the fiducial marks are directly formed on the wafer holder 25 also can be adopted. In this case, it is desirable that a concave portion is provided on the holder center to make the surfaces of the wafer W and the wafer holder 25 to be at the same height, and it is also desirable that material having high rigidity and low thermal expansion is used as the material of the wafer holder 25.

Note that, in the foregoing embodiment, description has been made for the case where the present invention is applied to an exposure apparatus having one wafer stage and one off-axis alignment detection system AS. The present invention is not limited to this, but can be applied to an exposure apparatus of a double-stage type having two alignment systems (FIA) as disclosed in Japanese Patent Laid-Open 10-163098. In this case, the TIS of each FIA can be measured.

In the foregoing embodiment, the ultraviolet light source such as a KrF excimer laser light source or a pulse laser light source in the vacuum ultraviolet region such as F₂ laser and an ArF excimer laser is used as the light source. Not being limited to these light sources, another vacuum ultraviolet light source such as an Ar₂ laser light source (an output wavelength of 126 nm) may be used. Alternatively, the vacuum ultraviolet light is not limited to the laser beam output from each of the above-described light sources. A higher harmonic wave may be used which is obtained with wavelength conversion into ultraviolet by using a non-linear optical crystal after amplifying single wavelength laser light, infrared or visible, emitted from a DFB semiconductor laser device or a fiber laser by a fiber amplifier having, for example, erbium (Er) (or both erbium and ytterbium (Yb)) doped.

Note that description has been made in each embodiment for the case where the present invention is applied to a scanning exposure apparatus of the step-and-scan method. But, it is a matter of course that the applicable scope of the present invention is not limited to this. Specifically, the present invention can be preferably applied to a reduction projection exposure apparatus of the step-and-repeat method.

An exposure apparatus of the embodiment can be made in the following manner. The illumination optical system and the projection optical system, which are constituted of a plurality of lenses, are built in the body of the exposure apparatus, and optical adjustment is performed thereon; The reticle stage RST and the wafer stage WST that consist of a number of mechanical parts are installed in the body of the exposure apparatus and are connected with electric wires and pipes, and then overall adjustment (electrical adjustment, operation check and the like) is performed. Note that the exposure apparatus is preferably made in a clean room where temperature, cleanness and the like are controlled.

The present invention can be applied not only to the exposure apparatus that manufactures semiconductors, but also to an exposure apparatus for liquid crystal displays that transfers a liquid crystal display device pattern onto a rectangular glass plate, an exposure apparatus for display units such as plasma displays and organic EL's, an exposure apparatus that transfers a device pattern onto a ceramic wafer and that is used for manufacturing thin film magnetic heads, and an exposure apparatus used for manufacturing imaging devices (CCD and the like), micro-machines, DNA chips and the like. Moreover, the present invention can be applied not only to an exposure apparatus for manufacturing micro devices such as semiconductor devices but also to an exposure apparatus transferring a circuit pattern onto a glass substrate or silicon wafer so as to produce a reticle or mask used by a light exposure apparatus, EUV (Extreme Ultraviolet) exposure apparatus, X-ray exposure apparatus, electron beam exposure apparatus, etc. Herein, the exposure apparatus using a DUV (deep ultraviolet) light, a VUV (vacuum ultraviolet) light or the like generally uses a transmission reticle, and a quartz glass, a quartz glass to which fluorine is doped, fluorite, magnesium fluoride or crystal is used as a reticle substrate. In addition, an X-ray exposure apparatus of a proximity method or an electron exposure apparatus use a transmission mask (a stencil mask or a membrane mask), and a silicon wafer or the like is used as a mask substrate.

<<Manufacture of Devices>>

Next, the manufacture of devices by using the above exposure apparatus and method will be described.

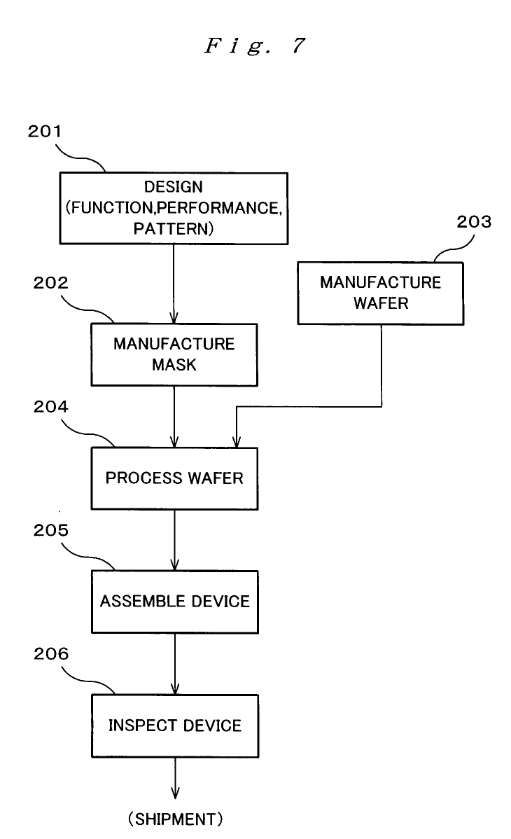

FIG. 7 is a flow chart for the manufacture of devices (semiconductor chips such as ICs or LSIs, liquid crystal panels, CCD's, thin magnetic heads, micro machines, or the like) in this embodiment. As shown in FIG. 7, in step 201 (design step), function/performance design for the devices (e.g., circuit design for semiconductor devices) is performed and pattern design is performed to implement the function. In step 202 (mask manufacturing step), masks on which a different sub-pattern of the designed circuit is formed are produced. In step 203 (wafer manufacturing step), wafers are manufactured by using silicon material or the like.

In step 204 (wafer-processing step), actual circuits and the like are formed on the wafers by lithography or the like using the masks and the wafers prepared in steps 201 through 203, as will be described later. In step 205 (device assembly step), the devices are assembled from the wafers processed in step 204. Step 205 includes processes such as dicing, bonding, and packaging (chip encapsulation).

Finally, in step 206 (inspection step), an operation test, durability test, and the like are performed on the devices. After these steps, the process ends and the devices are shipped out.

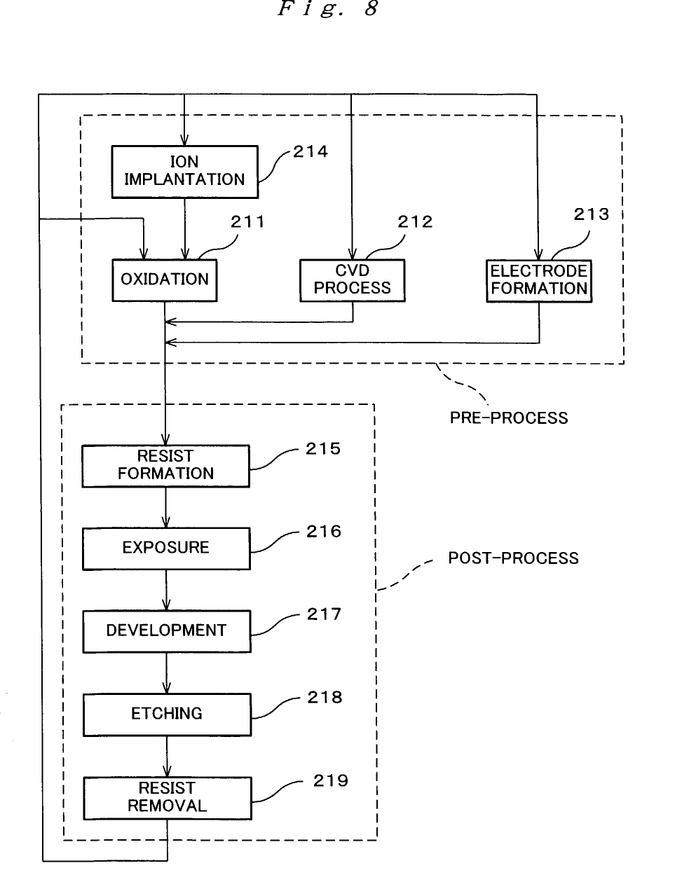

FIG. 8 is a flow chart showing a detailed example of step 204 described above in manufacturing semiconductor devices. Referring to FIG. 8, in step 211 (oxidation step), the surface of a wafer is oxidized. In step 212 (CVD step), an insulating film is formed on the wafer surface. In step 213 (electrode formation step), electrodes are formed on the wafer by vapor deposition. In step 214 (ion implantation step), ions are implanted into the wafer. Steps 211 through 214 described above constitute a pre-process, which is repeated, in the wafer-processing step and are selectively executed in accordance with the processing required in each repetition.

When the above pre-process is completed in each repetition in the wafer-processing step, a post-process is executed in the following manner. First of all, in step 215 (resist coating step), the wafer is coated with a photosensitive material (resist). In step 216, the above exposure apparatus transfers a sub-pattern of the circuit on a mask onto the wafer according to the above method. In step 217 (development step), the exposed wafer is developed. In step 218 (etching step), an uncovered member of portions other than portions on which the resist is left is removed by etching. In step 219 (resist removing step), the unnecessary resist after the etching is removed.

By repeatedly performing the pre-process and post-process, a multiple-layer circuit pattern is formed on each shot-area of the wafer.

According to the device manufacturing method of this embodiment described above, in the exposure step (step 216), the exposure apparatus and method of any of the above embodiments is used, and therefore it is possible to accurately transfer a reticle pattern onto wafers, so that productivity and yield in manufacturing of highly-integrated devices can be improved.

Although the embodiment of the present invention that has been described is a preferable current embodiment, the skilled in the art of a lithography system would easily conceive of making a lot of additions, variations and substitutions to the foregoing embodiment without departing from the spirit and the scope of the present invention. All of such additions, variations and substitutions are included in the scope of the present invention that is clarified most appropriately in the following claims.

What is claimed is:

1. A stage unit that holds a substrate, comprising:
a stage that moves within a two-dimensional plane;
a substrate holder, which is mounted on said stage, that holds said substrate and is capable of rotating through substantially 180° around a predetermined rotation axis orthogonal to the two-dimensional plane; and
a drive unit which can be mechanically connected to the substrate holder, and drives and rotates said substrate holder.

2. A measurement unit that measures a detection shift caused by a mark detection system, which optically detects a mark formed on a substrate, comprising:
a stage that moves within a two-dimensional plane;
a positional detection system that detects a position of said stage;
a substrate holder, which is mounted on said stage, that holds said substrate, is capable of rotating through substantially 180° around a predetermined rotation axis orthogonal to the two-dimensional plane, and have at least one fiducial mark arranged on a portion outside a holding plane for said substrate;
a drive unit which can be mechanically connected to said substrate holder, and drives and rotates said substrate holder;
a first detection control system that detects positional information of at least one particular fiducial mark out of said fiducial mark or marks and positional information of at least one selected alignment mark on said substrate by using said mark detection system and said positional detection system in a first state where the orientation of said substrate holder is set to a predetermined direction;
a second detection control system that detects positional information of each of said marks, whose positional information was detected in the first state, by using said mark detection system and said positional detection system in a second state where said substrate holder is rotated through 180° from the first state via the drive unit; and
an arithmetical unit which is electrically connected to said first and second detection control systems, and calculates a detection shift caused by said mark detection system by using the detection results of said first detection control system and said second detection control system.

3. The measurement unit according to claim 2,
wherein the detection results of said first detection control system and said second detection control system produce the positional information of one fiducial mark and of one particular alignment mark on said substrate.

4. The measurement unit according to claim 2,
wherein the detection results of said first detection control system and said second detection control system severally include the positional information of a plurality of same fiducial marks;
for each of said first and second states, said arithmetical unit statistically processes positional information of said plurality of fiducial marks to calculate the information regarding the position of said substrate holder in the state, and then calculates the detection shift caused by said mark detection system by using the calculation results.

5. The measurement unit according to claim 2,
wherein the detection results of said first detection control system and said second detection control system severally include the positional information of a plurality of same alignment marks;
for each of said first and second states, said arithmetical unit statistically processes positional information of said plurality of alignment marks to calculate the information regarding the position of said substrate in the state, and then calculates the detection shift caused by said mark detection system by using the calculation results.

6. An exposure apparatus that exposes a substrate with an energy beam to form a predetermined pattern on said substrate, comprising:
the measurement unit according to claim 2; and
a control unit that controls the position of said stage upon exposure so as to correct the detection shift caused by said mark detection system, the detection shift having been measured by said measurement unit.

7. A measurement unit comprising:
a stage which moves along a two-dimensional plane;
a position detection system which detects position of said stage in said two-dimensional plane;
a mark detection system which detects a mark present on said stage;
a substrate holder which is mounted on said stage, is capable of rotating through substantially 180° about a predetermined rotation axis perpendicular to said two-dimensional plane with being holding a substrate thereon, and of which a plurality of measurement marks are arranged on a face on which said substrate is mounted;
a driving unit which is mechanically connected to said substrate holder and drives said substrate holder to rotate;
a first detection control system which detects position information of said plurality of measurement marks by use of said position detection system and said mark detection system in a first state where the orientation of said substrate holder is set to a predetermined direction;
a second detection control system which, after having rotated said substrate holder through substantially 180° from said first state via said driving unit to be in a second state, detects position information of said plurality of measurement marks by use of said position detection system and said mark detection system in said second state; and
a first computing unit which is connected electrically to said first and second detection control systems and calculates a deformation amount of said substrate holder due to a change from said first state to said second state based on detecting results of said first and second detection control systems.

8. The measurement unit according to claim 7, wherein said plurality of measurement marks include a first mark arranged within a mount area of said substrate holder on which said substrate is mounted and a second mark formed outside said mount area of said substrate holder.

9. The measurement unit according to claim 8, wherein said first mark is formed on said substrate mounted on said mount area.

10. The measurement unit according to claim 9, wherein said substrate is an exclusively-for-measurement substrate of which the upper face is not coated with a photosensitive material.

11. The measurement unit according to claim 8, wherein said first detection control system detects position information of said first mark and said second mark in said first state,
wherein said second detection control system detects in said second state position information of said marks, of which said position information has been detected in said first state, and
wherein said first computing unit computes information on distance in said first state between said first mark and said second mark and information on distance in said second state between said marks, and calculates said deformation amount of said substrate holder based on the computing result.

12. The measurement unit according to claim 7, wherein said first detection control system detects in said first state position information of a plurality of measurement marks including a mark arranged within a mount area of said substrate holder on which said substrate is mounted,
wherein said second detection control system detects in said second state position information of a plurality of measurement marks including a mark arranged within a mount area of said substrate holder on which said substrate is mounted, and
wherein said first computing unit calculates said deformation amount of said substrate holder by use of first deformation information obtained by statistically processing position information of said plurality of measurement marks, detected by said first detection control system, and second deformation information obtained by statistically processing position information of said plurality of measurement marks, detected by said second detection control system.

13. The measurement unit according to claim 12, wherein said plurality of measurement marks detected by said second detection control system are same marks as said plurality of measurement marks detected by said first detection control system.

14. The measurement unit according to claim 7, wherein said plurality of measurement marks are arranged within a mount area of said substrate holder on which said substrate is mounted.

15. The measurement unit according to claim 14, wherein said plurality of measurement marks are formed on said substrate mounted on said mount area.

16. The measurement unit according to claim 15, wherein said substrate is an exclusively-for-measurement substrate of which the upper face is not coated with a photosensitive material.

17. The measurement unit according to claim 7, wherein each of said first detection control system and said second detection control system detects position information of a respective plurality of measurement marks, and
wherein said first computing unit calculates said deformation amount of said substrate holder by use of first deformation information obtained by statistically processing position information of said plurality of measurement marks, detected by said first detection control system, and second deformation information obtained by statistically processing position information of said plurality of measurement marks, detected by said second detection control system.

18. The measurement unit according to claim 17, wherein said plurality of measurement marks detected by said second detection control system are same marks as said plurality of measurement marks detected by said first detection control system.

19. The measurement unit according to claim 7, wherein said plurality of measurement marks include a substrate mark formed on said substrate mounted on said substrate holder and a fiducial mark formed outside a mount area of said substrate holder on which said substrate is mounted, said measurement unit further comprising:
a storage unit which stores a deformation amount of said substrate holder computed by said first computing unit;
a third detection control system which detects position information of said substrate mark and said fiducial mark by use of said position detection system and said mark detection system in a third state where the orientation of said substrate holder is set to be a same as in said first state;
a fourth detection control system which, after having rotated said substrate holder through substantially 180° from said third state via said driving unit to be in a fourth state, detects position information of said marks, of which said position information has been detected in said third state, by use of said position detection system and said mark detection system in said fourth state; and
a second computing unit which is connected electrically to said third and fourth detection control systems and calculates a seeming detection shift due to said mark detection system based on detecting results of said third and fourth detection control systems, and then calculates a real detection shift due to said mark detection system based on the calculating result and said deformation amount stored in said storage unit.

20. An exposure apparatus which exposes a substrate with an energy beam to form a predetermined pattern on said substrate, said exposure apparatus comprising:
the measurement unit according to claim 19; and
a controller which controls position of said stage upon exposure so as to correct for a real detection shift due to said mark detection system measured by said measurement unit.

21. A measurement method that measures a detection shift caused by a mark detection system, which optically detects marks formed on a substrate, the method comprising:
mounting the substrate, on which at least one alignment mark is formed, on a substrate holder where at least one fiducial mark is formed in the vicinity of its peripheral portion;
detecting at least one particular fiducial mark out of said fiducial mark or marks and at least one selected alignment mark on said substrate by using said mark detection system in a first state where the orientation of said substrate holder is set to a predetermined direction, and obtaining the positional information of each mark to be detected based on said detection results and a position of the substrate holder when each mark is detected;
detecting each mark to be detected by using said mark detection system in a second state where said substrate holder has been rotated through 180° from said first state around a predetermined rotation axis, which is substantially orthogonal to a mounting plane for said substrate, and obtaining the positional information of each mark to be detected based on said detection result and a position of the substrate holder when each mark is detected; and
calculating the detection shift caused by said mark detection system by using the positional information of each mark to be detected, which has been obtained based on the detection result of said mark detection system when the orientation of said substrate holder is in the first state and the detection result of said mark detection system when the orientation of the substrate holder is in the second state.

22. The measurement method according to claim 21,
wherein said each mark to be detected, the positional information of which is obtained based on the detection result of said mark detection system when the orientation of said substrate holder is in the first state and the detection result of said mark detection system when the orientation of the substrate holder is in the second state, is a set of one fiducial mark and one particular alignment mark on said substrate.

23. The measurement method according to claim 21,
wherein positional information obtained based on the detection result of said mark detection system when the orientation of said substrate holder is in the first state and positional information obtained based on the detection result of said mark detection system when the orientation of the substrate holder is in the second state severally include the positional information of a plurality of same fiducial marks;
in calculating said detection shift, for each of said first and second states, positional information of said plurality of fiducial marks is statistically processed to calculate the information regarding the position of said substrate holder in the state, and the detection shift caused by said mark detection system is calculated by using said calculation results.

24. The measurement method according to claim 23,
wherein the information regarding the position of said substrate holder contains an offset in a coordinate axis direction on an orthogonal coordinate system that defines the movement of said substrate holder.

25. The measurement method according to claim 21,
wherein positional information obtained based on the detection result of said mark detection system when the orientation of said substrate holder is in the first state and positional information obtained based on the detection result of said mark detection system when the orientation of the substrate holder is in the second state severally include the positional information of a plurality of same alignment marks;
in calculating said detection shift, for each of said first and second states, positional information of said plurality of alignment marks is statistically processed to calculate the information regarding the position of said substrate in the state, and the detection shift caused by said mark detection system is calculated by using said calculation results.

26. The measurement method according to claim 25,
wherein the information regarding the position of said substrate is obtained based on the mean value of pieces of positional information of said plurality of alignment marks.

27. The measurement method according to claim 25,
wherein the information regarding the position of said substrate contains an offset in a coordinate axis direction on an orthogonal coordinate system that defines the movement of said substrate holder.

28. An exposure method that exposes a substrate with an energy beam to form a predetermined pattern on said substrate, comprising:
measuring the detection shift caused by said mark detection system by the measurement method according to claim 21; and
controlling the position of said substrate holder upon exposure so as to correct for the detection shift caused by said mark detection system, the detection shift having been measured by said measurement method.

29. A device manufacturing method including a lithography process, wherein in said lithography process, exposure of a substrate is performed by use of the exposure method of claim 28.

30. A measurement method comprising:
a first step of detecting, by use of a mark detection system, a plurality of measurement marks arranged on a face of a substrate holder on which a substrate is mounted in a first state where the orientation of said substrate holder is set to a predetermined direction, said substrate holder being capable of holding said substrate, and obtaining position information of said plurality of measurement marks based on the detecting result and positions of said substrate holder each of which has been detected upon detection of a corresponding mark of said plurality of measurement marks;
a second step of detecting, by use of said mark detection system, said plurality of measurement marks in a second state where said substrate holder has been rotated through substantially 180° from said first state about a predetermined rotation axis substantially perpendicular to said substrate-mount face, and obtaining position information of said plurality of measurement marks based on the detecting result and positions of said substrate holder each of which has been detected upon detection of a corresponding mark of said plurality of measurement marks; and
a third step of calculating a deformation amount of said substrate holder due to a change from said first state to said second state by use of position information of said plurality of measurement marks obtained in said first and second steps.

31. The measurement method according to claim 30, wherein said plurality of measurement marks include a first mark formed on a substrate mounted on said substrate holder and a second mark formed outside a mount area of said substrate holder on which said substrate is mounted.

32. The measurement method according to claim 31, wherein in said first step, position information of said first mark and said second mark is detected in said first state,
wherein in said second step, position information of said marks, of which said position information has been detected in said first step, is detected in said second state and
wherein in said third step, information on distance in said first state between said first mark and said second mark and information on distance in said second state between said marks are computed, and said deformation amount of said substrate holder is calculated based on the computing result.

33. The measurement method according to claim 30, wherein in said first step, position information of a plurality of measurement marks including a mark formed on a substrate mounted on said substrate holder is detected in said first state,
wherein in said second step, position information of said marks, of which said position information has been detected in said first state, is detected in said second state and
wherein in said third step, said deformation amount of said substrate holder is calculated by use of first deformation information obtained by statistically processing position information of said plurality of measurement marks, detected in said first state, and second deformation information obtained by statistically processing position information of said marks, detected in said second state.

34. The measurement method according to claim 30, wherein in said first step and in said second step, position information of a same plurality of measurement marks formed on said substrate mounted on said substrate holder is obtained, and
wherein in said third step, said deformation amount of said substrate holder is calculated by use of first deformation information obtained by statistically processing position information of said plurality of measurement marks, obtained in said first step, and second deformation information obtained by statistically processing position information of said plurality of measurement marks, obtained in said second step.

35. The measurement method according to claim 30, further comprising:
a fourth step of detecting, by use of said mark detection system in a third state where the orientation of said substrate holder is set to be a same as in said first state, a substrate mark formed on said substrate mounted on said substrate holder and a fiducial mark formed outside a mount area of said substrate holder on which said substrate is mounted, said substrate mark and said fiducial mark being included in said plurality of measurement marks, and obtaining position information of said marks based on the detecting result and positions of said substrate holder each of which has been detected upon detection of a corresponding mark of said marks;
a fifth step of detecting positions of said marks, of which said position information has been detected in said third state, by use of said mark detection system in a fourth state where said substrate holder has been rotated through substantially 180° from said third state and obtaining position information of said marks based on the detecting result and positions of said substrate holder each of which has been detected upon detection of a corresponding mark of said marks; and
a sixth step of calculating a seeming detection shift due to said mark detection system based on detecting results of said fourth step and said fifth step, and then calculating a real detection shift due to said mark detection system based on the calculating result and said deformation amount calculated in said third step.

36. An exposure method with which to expose a substrate with an energy beam to form a predetermined pattern on said substrate, said exposure method comprising:
measuring a real detection shift due to said mark detection system according to the measurement method of claim 35; and
controlling position of said stage upon exposure so as to correct for said measured, real detection shift due to said mark detection system.

37. A device manufacturing method including a lithography process, wherein in said lithography process, exposure of a substrate is performed by use of the exposure method of claim 36.
